(19) United States
(12) Patent Application Publication
(10) Pub. No.: US 2015/0037517 A1
(43) Pub. Date: Feb. 5, 2015

(54) PROCESS FOR MAKING MATERIALS WITH MICRO- OR NANOSTRUCTURED CONDUCTIVE LAYERS

(71) Applicant: SABIC Global Technologies B.V., Amsterdam (NL)

(72) Inventors: Jillian M. BURIAK, Edmonton (CA); Tate C. HAUGER, Edmonton (CA); S. M. Ibrahim AL-RAFIA, Edmonton (CA); Amit K. TEVTIA, Thuwal (SA); Ahmed I. ABDELRAHMAN, Thuwal (SA); Ihab ODEH, Thuwal (SA)

(21) Appl. No.: 14/444,617

(22) Filed: Jul. 28, 2014

Related U.S. Application Data
(60) Provisional application No. 61/860,485, filed on Jul. 31, 2013.

(51) Int. Cl. H01B 13/00; B05D 1/18; B05D 1/32; B05D 3/02; B05D 1/28; B05D 1/26; B05D 3/12; B05D 1/02; B05D 1/00

(52) U.S. Cl. CPC H01B 13/0016; H01B 13/0026; B05D 1/02; B05D 1/18; B05D 1/32; B05D 1/005; B05D 1/28; B05D 1/26; B05D 3/12; B05D 3/0254
USPC 427/600; 427/108; 427/58

(57) ABSTRACT

Disclosed are methods for making conductive materials. The methods can be used to make transparent, opaque, or reflective electrodes by using the same materials and equipment but varying the processing conditions or amounts of materials used. The methods can include: (a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate; (b) applying heat to heat the substrate surface to a temperature that is greater than the glass transition temperature or the Vicat softening temperature of the substrate and less than the melting point of the substrate; (c) applying pressure such that the substrate and the micro- or nanostructures are pressed together; and (d) removing the pressure to obtain the conductive material.

### CROSS-REFERENCE TO RELATED APPLICATIONS

This application claims the benefit of U.S. Provisional Application No. 61/860,485, filed Jul. 31, 2013, the contents of which are incorporated by reference.

### BACKGROUND OF THE INVENTION

A. Field of the Invention

The invention generally concerns a process for making electrically conductive materials that can be used in a wide-array of applications and electronic devices. In particular, the invention concerns a process for making a conductive micro- or nanostructured layer on at least a portion of the surface of a substrate by simultaneous application of heat and pressure to sufficiently attach disposed micro- or nanostructures to the substrate's surface and to create the conductive micro or nanostructured layer from the disposed micro- or nanostructures. Notably, no pre-conditioning steps of the substrate's surface are needed to sufficiently attach the conductive structures to the substrate.

B. Description of Related Art

With the rapid growth of research in flexible electronics, there is enormous demand for both transparent and reflective bendable electrodes (Angmo & Krebs, 2013; De, et al., 2010; Liu & Yu, 2011). Examples of such applications include lightweight polymer- and small molecule-based organic photovoltaics (OPVs), organic light emitting diodes (OLEDs), and displays (Belenkova, et al., 2012). The inorganic semiconductor, indium tin oxide (ITO), is the most widely used material as the transparent conducting electrode, but the lack of flexibility and rising price due to limited earth abundance underscore the need for a bendable replacement with low processing cost (Emmott, et al., 2012; Chung, et al., 2012; Azzopardi, et al., 2011; Krebs, et al., 2010).

While a number of possible alternatives to ITO have been proposed, some of which attempt to use nanostructure-based materials (e.g., nanowires), the process used to sufficiently attach conductive structures to a substrate typically relies on a pre-conditioning step. For example, there have been numerous attempts to chemically modify or functionalize either or both the substrate layer and the conductive material. Such modifications can be costly, complex and time consuming, and introduce materials that can negatively affect the performance of the resulting electrode. Other attempts rely on the use of an adhesive material to increase attachment of nanowires to a substrate. In one instance, WO 2012/063024 proposes using a substrate that has a base layer and a polymeric binding layer with the goal of increasing the attachment between nanowires and the substrate via the polymeric binding layer. Similarly, U.S. Pat. No. 8,049,333 proposes the use of a matrix material to increase the attachment with one difference—nanowires are first placed on the substrate and then the matrix material is added so as to increase adhesion. Another example of pre-conditioning is illustrated in U.S. 2009/0056854, which utilizes manufactured recesses or “pores” in the surface of the substrate and pressure or heat such that the pores close up and attach to a portion of the conductive material, thereby increasing the attachment of conductive material to the substrate. In a further example of a pre-conditioning step, U.S. 2011/0094651 uses an adhesive layer such as those discussed above along with multiple rollers to apply pressure from the upper and lower surfaces of a substrate so as to attach conductive material to one of the surfaces of the substrate. Subsequently, and after the initial pressure step, both pressure and heat are used in an attempt to create a conductive layer on the substrate.

### SUMMARY OF THE INVENTION

A solution to avoiding the use of the aforementioned pre-conditioning steps has been discovered. The discovery is based on the simultaneous application of both heat and pressure to micro-structures or nanostructures (or a combination of both micro- and nanostructures) that have been deposited onto a substrate, the result of which is the production of a micro- or nanostructured conductive layer that is sufficiently attached (e.g., passes the scotch tape test or the bending test) to the substrate's surface without the need of any pre-conditioning steps. This allows for a cost-efficient and scalable process when compared with known processes that rely on pre-conditioning steps.

Notably, the process of the present invention can be used to prepare either reflective or non-reflective conductive materials starting from the same substrate. By way of example, the process allows one to start with a transparent or translucent substrate (e.g., polyethylene terephthalates (PET)) and to dispose a sufficient amount of micro- or nanostructures onto the substrate such that after the simultaneous application of heat and pressure, the resulting micro- or nanostructured conductive layer can either be opaque, reflective, or transparent or translucent. In this sense, the opacity, reflectivity, and/or transparency of the electrodes produced by the processes of the present invention can be tuned or modified as desired by varying any one of or any combination of the following parameters: (a) varying the amount of the micro- or nanostructures deposited on the substrate surface; (b) varying the amount of pressure used (e.g., varying the roller pressure); (c) varying the temperature/heat; and/or (d) varying the micro- or nanostructure type or types being used. Therefore, the present invention allows one to use the same process and the same materials to produce opaque, reflective, translucent, or transparent conductive materials such as electrodes. Still further, the same equipment can be used to produce a desired electrode. For example, opaque electrodes, reflective electrodes, transparent electrodes, and translucent electrodes can be prepared on the same equipment (e.g. roll-to-roll processing equipment). This coupled with the cost-efficiency and scalability of the process of the present invention provides a unique solution to current problems seen in producing conductive materials.

Additionally, the sheet resistance of the electrodes produced by the processes of the present invention can be tuned as desired for a given electronic application. Of note, the same parameters that are used to tune the opacity, reflectivity, and transparency of the electrodes can also be used to tune the resistance of the electrodes. For example, the resistance can be tuned by any one of or any combination of the following parameters: (a) varying the amount of the micro- or nanostructure composition deposited on the substrate surface; (b) varying the amount of pressure used (e.g., varying the roller pressure); (c) varying the temperature/heat; and/or (d) varying the micro- or nanostructure type or types being used.

In one embodiment, there is disclosed a method for making a conductive material comprising a substrate and a conductive layer that is attached to said substrate. The method includes: (a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate; (b) applying heat to the first surface of the substrate with a heating source such that the micro- or nanostructures or the first surface of the substrate are heated to a temperature that is greater than the glass transition temperature or the Vicat softening temperature of the substrate and less than the melting point of the substrate; (c) applying a sufficient amount of pressure with a pressure source to the second surface of the substrate such that the first surface of the substrate and the micro- or nanostructures are pressed together so as to form a conductive layer that is attached to the first surface of the substrate; and (d) removing the pressure source to obtain the conductive material, wherein the sheet resistance of the conductive material in step (d) is less than the sheet resistance of the substrate in step (a). The first surface can include nanostructures or microstructures or combinations of both disposed on the portion of the first surface. The micro- or nanostructures can be disposed on at least 1, 5, 10, 20, 30, 40, 50, 60, 70, 80, 90, or 100% of the surface area of the first surface of the substrate in step (a). Further, the micro- or nanostructures can be formed into a specified pattern on the first surface of the substrate. The portion of the resulting conductive layer can be embedded into at least a portion of the first surface of the substrate. Further, the resulting conductive layer can be attached to the substrate such that it retains its conductivity after being subjected to a scotch tape test or a bending test. In some instances, the first surface is not pre-conditioned to increase attachment between the micro- or nanostructured layer and the substrate in step (a) such that (i) the first surface is not chemically modified or functionalized, (ii) the first surface is not physically altered such as by creating a recess in said surface, (iii) an adhesive is not used or disposed on the first surface of the substrate, or (iv) an initial pressure or heat step prior to simultaneous application of pressure and heat is not performed. With respect to (iv), and in instances where the substrate is first produced via an extrusion process, the produced substrate is not subsequently subjected to an initial pressure or heat step prior to simultaneous application of pressure and heat. In certain aspects, the micro- or nanostructures are micro- or nanowires, micro- or nanoparticles, micro- or nanospheres, micro- or nanorods, micro- or nano-tetrapods, or micro- or nano-hyperbranched structures or mixtures thereof. The micro- or nanostructures can be deposited directly onto the surface of the substrate in step (a) by spray coating, ultra sonic spray coating, roll-to-roll coating, ink jet printing, screen printing, drop casting, spin coating, dip coating, Mayer rod coating, gravure coating, slot die coating, or doctor blade coating of a composition comprising the micro- or nanostructures. The composition comprising micro- or nanostructures can include nanostructures solubilized or suspended in a solvent such as an aqueous solvent, an alcohol, a polar hydrocarbon, a chlorinated solvent or a combination thereof. The micro- or nanostructures can be coated with either an organic ligand comprising a thiol, a phosphorus, an amine or a combination of thereof. The polymeric ligand can be polyvinylpyrrolidone or polyphenylene vinylene, polylysine, or a combination thereof. In certain aspects, the substrate or the micro- or nanostructures are heated to a temperature within at least 80% of the Vicat softening point of the substrate. In particular instances, the heating step (b) and pressure step (c) are performed simultaneously or substantially simultaneously. In other instances, the heating step (b) is started before pressure step (c) and then during heating or after sufficient heating the pressure step (c) is performed. The heating source can be in direct contact with the micro- or nanostructures or in direct contact with the substrate or a combination thereof. In particular instances, the heating source directly contacts at least 10, 20, 30, 40, 50, 60, 70, 80, 90 or 100% of the deposited micro- or nanostructures or more particularly at least 50, 60, 70, or 80% of said micro- or nanostructures or indirectly contacts at least 10, 20, 30, 40, 50, 60, 70, 80, 90 or 100% (or preferably 50, 60, 70, or 80%) of the micro- or nanostructures that are embedded below the top surface of the substrate. By indirect, it is meant that the micro- or nanostructures do not directly contact the heating source but are in a sufficiently close proximity to be indirectly heated when the heating source contacts the top surface of the substrate. In some instances, the pressure source can be a roller or can be a weight applied to the second surface of the substrate such that the substrate is in between the heating source and the pressure source. In instances where the pressure source is a roller, the roller can be a metallic roller or a ceramic roller or a plastic roller or a rubber roller. The pressure applied by the roller can be a range of 25 to 300 psi or an equivalent of such pressure (e.g., a load or line pressure represented in kgf/cm) (or 50 to 250 psi or 75 to 225 psi, or 100 to 200 psi) or the speed at which the roller moves across the second surface of the substrate is at least 0.1 cm/s up to 100 cm/s (or 0.5 to 90 cm/s or 1 to 90 cm/s, or 5 to 80 cm/s, or 10 to 70 cm/s or 20 to 60 cm/s or 30 to 50 cm/s). In particular instances, the pressure applied by the roller can be 25 to 300 psi or an equivalent of such pressure (e.g., a load or line pressure represented in kgf/cm) at a speed of 0.5 to 12 cm/s or 50 to 250 psi at a speed of 1 to 10 cm/s. In some aspects, the substrate can be a non-conductive substrate, and the produced conductive material has a sheet resistance of less than 50 ohm per square (Ω/□), 40Ω/□, 30Ω/□, 20Ω/□, or 10Ω/□. In particular instances, the substrate can be a polyethylene terephthalate (PET). Additional non-limiting substrates that can be used in the context of the present invention are provided below and incorporated here by reference (e.g. a polymeric substrate, a glass substrate, a quartz substrate, or a non-electrically conductive substrate or a flexible or elastomeric polymeric substrate such as Polyethylene terephthalate (PET), a polycarbonate (PC) family of polymers, polybutylene terephthalate (PBT), Poly(1,4-cyclohexylidene cyclohexane-1,4-dicarboxylate) (PCCD), Glycol modified polycyclohexyl terephthalate (PCTG), Poly(phenylene oxide (PPO), Polypropylene (PP), Polyethlyene (PE), Polyvinyl chloride (PVC), Polystyrene (PS), Poly(methyl methacrylate) (PMMA), Polyethyleneimine (PEI) and its derivatives, Thermoplastic elastomer (TPE), Terephthalic acid (TPA) elastomers, poly(cyclohexanedimethylene terephthalate) (PCT), Polyethylene naphthalate (PEN), Polyamide (PA), Polystyrene sulfonate (PSS), or Polyether ether ketone (PEEK) or combinations or blends thereof. The conductive layer can include a plurality of intersections between the micro- or nanostructures such that conductivity of the conductive layer is improved when compared with the micro- or nanostructures deposed on the substrate in step (a). The cross-sections of the micro- or nanostructures in the conductive layer can have flatter cross-sections when compared with the micro- or nanostructures deposed on the substrate in step (a). In particular instances, the substrate can be transparent or can be translucent or can be opaque or reflective. In certain instances wherein the substrate is transparent or translucent, the resulting conductive material can be transparent or translucent or opaque or reflective. In this sense, the reflectivity/transparency/translucency of the resulting conductive material can be tuned or modified as desired by modifying the amount of the micro- or nanostructures disposed on the first surface of the substrate in step (a), or the speed and pressure of rolling in steps (b) and (c) or all of steps (a), (b), and (c). By increasing the amount of said micro- or nanostructure disposed in step (a), one can increase the reflectivity of the resulting conductive material. Alternatively, by decreasing the amount of said micro- or nanostructure disposed in step (a), one can decrease the reflectivity of the resulting conductive material. In one instance, the substrate can have a total transmittance of incident light of at least 50, 60, 70, 80, 90%, or more. In particular instances, the resulting conductive material can be tuned to have a total transmittance of incident light of 0, 10, 20, 30, 40, 50, 60, 70, 80, or 90% or more or can have a total transmittance of incident light of at least 50, 60, 70, 80, or 90%, or more. In certain aspects, the substrate can be opaque and the conductive layer can be transparent, translucent, opaque or reflective. Alternatively, the substrate can be transparent or translucent, and the conductive layer can be transparent, translucent, opaque, or reflective. The conductive material can be an electrode such as a transparent electrode, a translucent electrode, or a reflective electrode. The micro- or nanostructures can include or be made of metal or carbon or can be mixtures of metal and carbon. Non-limiting examples of metal include silver, gold, copper, or nickel, platinum, palladium, chromium, aluminum or any combination thereof. A non-limiting example of carbon includes graphene. The conductive layer of the resulting conductive material can have a roughness of 20 to 200 nm peak to peak or a 10 to 50 nm rms roughness or can have a roughness that allows for said material to be used effectively as an electrode. The conductive layer can have a thickness between 20 nm to 20 μm and can cover at least 1, 5, 10, 20, 30, 40, 50, 60, 70, 80, 90, or 100% of the first surface of the substrate. The conductive layer can have a predefined pattern. In certain aspects, the conductive material does not include an indium tin oxide layer. The conductive material can be flexible with a radius of curvature down to 0.625 mm. The applications of the conductive materials of the present invention are wide. By way of example only, the conductive material can be incorporated into an electronic device. The electronic device can be a transistor, a resistor, a logic device, sensors, antennas, integrated circuits, electroluminescence devices or a field effect device. The electronic device can be an optoelectronic device (e.g., a touch panel, a liquid crystal display, a solar cell, a sensor, a memory element, an antenna, or a light emitting diode). The conductive material can be a transparent or translucent electrode or an opaque or reflective electrode. The conductive material can be incorporated into a photovoltaic cell. An electronic material layer can be deposited onto the conductive layer and wherein a second conductive layer or electrode can be deposited onto the electronic material layer. An electron donor layer, an electron accepting layer, or any combination thereof can be deposited onto the conductive layer, and a second conductive layer or electrode can be deposited onto the electron donor layer.

In another aspect of the present invention, there is disclosed a method for making a conductive material comprising a substrate and a conductive layer that is attached to said substrate. The method can include: (a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate; (b) applying heat to either the first surface or the second surface of the substrate, or both, with at least a first heating source or with at least a first and second heating source such that the micro- or nanostructures or the first surface of the substrate are heated to a temperature that is greater than the glass transition temperature or the Vicat softening temperature of the substrate and less than the melting point of the substrate; (c) applying a sufficient amount of pressure to either the first surface or the second surface of the substrate, or both, with at least a first pressure source or with a first and second pressure source such that the first surface of the substrate and the micro- or nanostructures are pressed together so as to form a conductive layer that is attached to the first surface of the substrate; and (d) removing the first pressure source or the first and second pressure sources to obtain the conductive material, wherein the sheet resistance of the conductive material in step (d) is less than the sheet resistance of the substrate in step (a). The first surface of the substrate can be heated with a heating source and pressure can be applied to the second surface of the substrate with a pressure source. In one instance, the heating source can comprise a heated surface that simultaneously contacts at least 50, 60, 70, 80, 90 or 100% of the micro- or nanostructures disposed on the first surface of the substrate and the pressure source can be a roller. In one aspect, the second surface of the substrate can be heated with a heating source and pressure can be applied to the first surface of the substrate with a pressure source. The heating source can include a heated surface that simultaneously contacts at least 50, 60, 70, 80, 90 or 100% of the second surface of the substrate and the pressure source is a roller. In another aspect, the first surface of the substrate can be heated with a first heating source and the second surface of the substrate can be heated with a second heating source, wherein the heating sources are also pressure sources that apply pressure to their respective surfaces. The first and second heating sources can each be a roller. The additional processing steps and uses of the resulting conductive material discussed in the above paragraph and throughout this specification can also be used with the process discussed with the method discussed in this paragraph.

In yet another embodiment there is disclosed a conductive material that is made by the processes of the present invention. The conductive material can be a transparent conductive material, a translucent conductive material, an opaque conductive material, or a reflective conductive material. In one particular instance, the conductive material can be a transparent electrode or a reflective electrode, wherein the conductive layer provides conductivity across at least a portion of the first surface of the substrate. The electrodes or conductive materials can be flexible or rigid/non-flexible. The micro- or nanostructures can have widths of less than 100, 90, 80, 70, 60, 50, 40, 30, 20, or 10 nm and aspect ratios of 1, 5, 10, 20, 30, 40, 50, or greater. The transparency of the conductive layer can be at least 50, 60, 70, 80, 85, 90%, or more. The conductive layer can cover 1, 5, 10, 15, 20, 30, 40, 50, 60, 70, 80, 90, or 100% of the first surface of the substrate. In particular instances, it can cover less than 50, 40, or 30% of the first surface of the substrate. The conductive material or conductive layer can have a greater than 50% specular transmission or greater than 65% diffuse transmission. The sheet resistance of the conductive layer or of the conductive material can be less than 100, 90, 80, 70, 60, 50, 40, 30, or 20Ω/□. The conductive layer or the conductive material can have a work function between 3.5 and 5.5 eV or from 1 to 10 eV or from 2 to 8 eV or from 3 to 7 eV. The conductive material can have a smooth surface with surface height variations ranging from 5 nm to 50 nm. The incident radiation from an electrode of the present invention can be from about 300 nm to 900 nm. As noted above and discussed throughout the specification, the conductive materials can be incorporated into a variety of devices. The conductive material can be used as an anode, a cathode, or both in electronic devices. The conductive layer can have a surface modification layer deposited directly on it. The conductive layer can have an electron donating, an electron accepting or any combination thereof deposited directly on it, or directly on the modification layer. A second electrode (either transparent or reflective or translucent) can be deposited directly, or through the use of a surface modification layer, on top of the electron donor/acceptor combination. In one aspect, the transparent electrode can be transparent and can be deposited on the top of an optoelectronic active layer which comprises an optically thick electrode, surface modification layers, electron donating and accepting materials or any combination thereof. In certain aspects, the transparent electrode can be the last component to be deposited on an OPV device fabricated on a reflective or opaque electrode. The transparent electrode can be used as any component in a tandem solar cell or is used as a recombination layer in a tandem solar cell. The transparent electrode is used in a light emitting device (e.g., LED or OLED). The conductive film or transparent electrode can be used as one or more electrodes in either top emitting, or bottom emitting OLEDs. The conductive film or transparent electrode can be used as one or more electrodes in transparent OLEDs. The conductive material can be used in a thin film transistor. The conductive material can be used as a gate in thin film transistors (TFTs) or is used or is modified to be used as either a source or drain in TFTs. The conductive material can be used as an electrode is read/write logic memory. The conductive material can be used as an electrical bus in logic memory applications. In particular instances where the conductive material is reflective or wherein the conductive material is a reflective electrode, the substrate can either be opaque or reflective or can be transparent or translucent. Similar to the transparent and translucent electrodes of the present invention, the reflective electrodes can be used in all types of electronic devices. In particular instances where a device uses both reflective and transparent electrodes, the process of the present invention can be used to make both of said electrodes (e.g., photovoltaic device).

Also disclosed in the context of the present invention are embodiments 1 to 120. Embodiment 1 is a method for making a conductive material comprising a substrate and a conductive layer that is attached to said substrate, the method comprising: (a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate; (b) applying heat to the first surface of the substrate with a heating source such that the micro- or nanostructures of the first surface of the substrate are heated to a temperature that is greater than the glass transition temperature or the Vicat softening temperature of the substrate and less than the melting point of the substrate; (c) applying a sufficient amount of pressure with a pressure source to the second surface of the substrate such that the first surface of the substrate and the micro- or nanostructures are pressed together so as to form a conductive layer that is attached to the first surface of the substrate; and (d) removing the pressure source to obtain the conductive material, wherein the sheet resistance of the conductive material in step (d) is less than the sheet resistance of the substrate in step (a). Embodiment 2 is the method of embodiment 1, wherein at least a portion of the conductive layer is embedded into at least a portion of the first surface of the substrate. Embodiment 3 is the method of any one of embodiments 1 to 2, wherein the conductive layer is attached to the substrate such that it retains its conductivity after being subjected to a scotch tape test or a bending test. Embodiment 4 is the method of any one of embodiments 1 to 3, wherein the first surface is not pre-conditioned to increase attachment between the micro- or nanostructures and the substrate in step (a) such that (i) the first surface is not chemically modified or functionalized, (ii) the first surface is not physically altered such as by creating a recess in said surface, (iii) an adhesive is not used or disposed on the first surface of the substrate, or (iv) an initial pressure or heat step prior to simultaneous application of pressure and heat is not performed. With respect to (iv), and in instances where the substrate is first produced via an extrusion process, the produced substrate is not subsequently subjected to an initial pressure or heat step prior to simultaneous application of pressure and heat. Embodiment 5 is the method of any one of embodiments 1 to 4, wherein the first surface of the substrate comprises a combination of nanostructures and microstructures. Embodiment 6 is the method of any one of embodiments 1 to 5, wherein the micro- or nanostructures are micro- or nanowires, micro- or nanoparticles, micro- or nanospheres, micro- or nanorods, micro- or nano-tetrapods, or micro- or nano-hyperbranched structures or mixtures thereof. Embodiment 7 is the method of any one of embodiments 1 to 6, wherein the micro- or nanostructures are disposed directly onto the surface of the substrate in step (a) by spray coating, ultra sonic spray coating, roll-to-roll coating, ink jet printing, screen printing, drop casting, spin coating, dip coating, Mayer rod coating, gravure coating, slot die coating, or doctor blade coating of a composition comprising the micro- or nanostructures. Embodiment 8 is the method of embodiment 7, wherein the composition comprising micro- or nanostructures includes nanostructures solubilized or suspended in a solvent such as an aqueous solvent, an alcohol, a polar hydrocarbon, a chlorinated solvent or a combination thereof. Embodiment 9 is the method of embodiment 8, wherein the micro- or nanostructures are coated with an organic ligand comprising a thiol, a phosphorus, an amine or a combination of thereof. Embodiment 10 is the method of embodiment 9, wherein the polymeric ligand is polyvinylpyrrolidone, polyphenylene vinylene, polylysine, or a combination thereof. Embodiment 11 is the method of any one of embodiment 1-10, wherein the substrate or the micro- or nanostructures are heated to a temperature within at least 80% of the Vicat softening point of the substrate. Embodiment 12 is the method of any one of embodiments 1-11, wherein heating step (b) and pressure step (c) are performed simultaneously or substantially simultaneously or wherein the heating step (b) is performed before pressure step (c). Embodiment 13 is the method of any one of embodiments 1-12, wherein the heating source comprises a heated surface that directly contacts at least 50, 60, 70, 80, 90 or 100% of micro- or nanostructures on the top surface of the substrate or indirectly contacts at least 50, 60, 70, 80, 90 or 100% of the micro- or nanostructures that are embedded below the top surface of the substrate. By indirect, it is meant that the micro- or nanostructures do not directly contact the heating source but are in a sufficiently close proximity to be indirectly heated when the heating source contacts the top surface of the substrate. Embodiment 14 is the method of any one of embodiments 1-13, wherein the pressure source is a roller. Embodiment 15 is the method of embodiment 14, wherein the roller is a metallic roller. Embodiment 16 is the method of any one of embodiments 14-15, wherein the pressure applied by the roller is between 25 to 300 psi. Embodiment 17 is the method of any one of embodiments 14-16, wherein the speed at which the roller moves across the second surface of the substrate is at least 0.1 cm/s up to 100 cm/s. Embodiment 18 is the method of any one of embodiments 16 to 17, wherein the pressure applied by the roller is 25 to 300 psi at a speed of 0.5 to 12 cm/s or wherein the pressure applied by the roller is 50 to 250 psi at a speed of 1 to 10 cm/s. Embodiment 19 is the method of embodiments 18, wherein the substrate is non-conductive, and wherein the produced conductive material has a sheet resistance of less than 50Ω/□, 40Ω/□, or 30Ω/□. Embodiment 20 is the method of embodiments 19, wherein the substrate is polyethylene terephthalate (PET). Embodiment 21 is the method of any one of embodiments 1-20, wherein the conductive layer comprises a plurality of intersections between the micro- or nanostructures such that conductivity of the conductive layer is improved when compared with the micro- or nanostructures deposed on the substrate in step (a). Embodiment 22 is the method of any one of embodiments 1-21, wherein the cross-sections of the micro- or nanostructures in the conductive layer have flatter cross-sections when compared with the micro- or nanostructures deposed on the substrate in step (a). Embodiment 23 is the method of any one of embodiments 1-22, wherein the substrate is transparent, translucent, or opaque. Embodiment 24 is the method of any one of embodiments 1-23, wherein the conductive layer is transparent, translucent, or opaque. Embodiment 25 is the method of embodiment 24, wherein the transparency, translucency, or opacity of the conductive micro- or nanostructure layer is dependent on the amount of micro- or nanostructures within said layer. Embodiment 26 is the method of embodiment 25, wherein the substrate is transparent or translucent and the conductive layer is opaque or reflective. Embodiment 27 is the method of embodiment 26, wherein the substrate has a total transmittance of incident light of at least 50, 60, 70, 80, or 90%. Embodiment 28 is the method of embodiment 25, wherein the substrate is opaque or reflective and the conductive micro- or nanostructure layer is transparent, translucent, opaque or reflective. Embodiment 29 is the method of any one of embodiments 1 to 28, wherein the conductive material is transparent or translucent. Embodiment 30 is the method of embodiment 29, wherein the conductive material has a total transmittance of incident light of at least 50, 60, 70, 80, or 90%. Embodiment 31 is the method of embodiment 30, wherein the conductive material is an electrode. Embodiment 32 is the method of any one of embodiments 1 to 27, wherein the conductive material is opaque or reflective. Embodiment 33 is the method of embodiment 32, wherein the conductive material is an electrode. Embodiment 34 is the method of any one of embodiments 1 to 33, wherein the substrate is a polymeric substrate, a glass substrate, a quartz substrate, or a non-electrically conductive substrate. Embodiment 35 is the method of embodiment 34, wherein the polymeric substrate is a flexible or elastomeric polymeric substrate. Embodiment 36 is the method of embodiment 35, wherein the flexible or elastomeric polymeric substrate is a polyethylene terephthalate (PET), a polycarbonate (PC) family of polymers, polybutylene terephthalate (PBT), Poly(1,4-cyclohexylidene cyclohexane-1,4-dicarboxylate) (PCCD), Glycol modified polycyclohexyl terephthalate (PCTG), Poly(phenylene oxide) (PPO), Polypropylene (PP), Polyethylene (PE), Polyvinyl chloride (PVC), Polystyrene (PS), polymethamethyl acrylate (PMMA), Polyethyleneimine (PEI) and its derivatives, Thermoplastic elastomer (TPE), Terephthalic acid (TPA) elastomers, poly(cyclohexanedimethylene terephthalate) (PCT), Polyethylene naphthalate (PEN), Polyamide (PA), Polystyrene sulfonate (PSS), or Polyether ether ketone (PEEK) or combinations or blends thereof. Embodiment 37 is the method of any one of embodiments 1 to 36, wherein the micro- or nanostructures comprise metal or carbon or are a mixture of metal micro- or nanostructures and carbon micro- or nanostructures. Embodiment 38 is the method of embodiment 37, wherein the metal is a transition metal including but not limited to silver, gold, copper, or nickel, platinum, palladium, chromium, aluminum or any combination thereof. Embodiment 39 is the method of embodiment 37, wherein the carbon is graphene. Embodiment 40 is the method of any one of embodiments 1 to 39, wherein the conductive layer has a roughness of 20 to 200 nm peak to peak or a 10 to 50 nm rms roughness. Embodiment 41 is the method of any one of embodiments 1 to 40, wherein the conductive layer has a thickness between 20 nm to 20 μm or covers at least 10 to 100% of the first surface of the substrate. Embodiment 42 is the method of any one of embodiments 1 to 41, wherein the conductive material does not include an indium tin oxide layer. Embodiment 43 is the method of any one of embodiments 1 to 42, wherein the conductive material is flexible with a radius of curvature down to 0.625 mm. Embodiment 44 is the method of any one of embodiments 1 to 43, wherein the conductive material is incorporated into an electronic device. Embodiment 45 is the method of embodiment 44, wherein the electronic device is a transistor, a resistor, a logic device, a sensor, an antenna, an integrated circuit, an electroluminescence device or a field effect device. Embodiment 46 is the method of embodiment 44, wherein the electronic device is an optoelectronic device. Embodiment 47 is the method of embodiment 46, wherein the optoelectronic device is a touch panel, a liquid crystal display, a solar cell, a sensor, a memory element, an antenna, or a light emitting diode. Embodiment 48 is the method of any one of embodiments 44 to 47, wherein the conductive material is a transparent or translucent electrode. Embodiment 49 is the method of any one of embodiments 44 to 47, wherein the conductive material is a reflective or an opaque electrode. Embodiment 50 is the method of any one of embodiments 1 to 43, wherein the conductive material is incorporated into a photovoltaic cell. Embodiment 51 is the method of embodiments 50, wherein an electronic material layer is deposited onto the conductive layer and wherein a second conductive layer is deposited onto the electronic material layer. Embodiment 52 is the method of embodiment 50, wherein an electron donor layer, an electron accepting layer, or any combination thereof is deposited onto the conductive layer, and a second conductive layer is deposited onto the electron donor layer, electron donor layer, an electron accepting layer, or any combination thereof. Embodiment 53 is the method of any one of embodiments 50 to 52, wherein the conductive material is a transparent or translucent electrode. Embodiment 54 is the method for making a conductive material comprising a substrate and a conductive layer that is attached to said substrate, the method comprising: (a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate; (b) applying heat to either the first surface or the second surface of the substrate, or both, with at least a first heating source or with at least a first and second heating source such that the micro- or nanostructures or the first surface of the substrate are heated to a temperature that is greater than the glass transition temperature or the Vicat softening temperature of the substrate and less than the melting point of the substrate; (c) applying a sufficient amount of pressure to either the first surface or the second surface of the substrate, or both, with at least a first pressure source or with a first and second pressure source such that the first surface of the substrate and the micro- or nanostructures are pressed together so as to form a conductive layer that is attached to the first surface of the substrate; and (d) removing the first pressure source or the first and second pressure sources to obtain the conductive material, wherein the sheet resistance of the conductive material in step (d) is less than the sheet resistance of the substrate in step (a). Embodiment 55 is the method of embodiment 54, wherein the first surface of the substrate is heated with a heating source and pressure is applied to the second surface of the substrate with a pressure source. Embodiment 56 is the method of embodiment 55, wherein the heating source comprises a heated surface that simultaneously contacts at least 50, 60, 70, 80, 90 or 100% of the micro- or nanostructures disposed on the first surface of the substrate and the pressure source is a roller. Embodiment 57 is the method of embodiment 54, wherein the second surface of the substrate is heated with a heating source and pressure is applied to the first surface of the substrate with a pressure source. Embodiment 58 is the method of embodiment 57, wherein the heating source comprises a heated surface that simultaneously contacts at least 50, 60, 70, 80, 90 or 100% of the second surface of the substrate and the pressure source is a roller. Embodiment 59 is the method of embodiment 54, wherein the first surface of the substrate is heated with a first heating source and the second surface of the substrate is heated with a second heating source, wherein the heating sources are also pressure sources that apply pressure to their respective surfaces. Embodiment 60 is the method of embodiment 59, wherein the first and second heating source are each a roller. Embodiment 61 is the method of any one of embodiments 1 to 60, wherein the conductive layer is transparent and the substrate is transparent and non-conductive or wherein the conductive material is transparent. Embodiment 62 is the method of embodiment 61, wherein conductive layer is a designed pattern that provides conductivity across at least a portion of the first surface of the substrate. Embodiment 63 is the method of any one of embodiments 61 to 62, wherein the micro- or nanostructures have widths of less than 100 nm and aspect ratios of 20 or greater. Embodiment 64 is the method of any one of embodiments 61 to 63, wherein the micro- or nanostructures are deposited on the first surface of the substrate via solution based processing. Embodiment 65 is the method of any one of embodiments 61 to 64, wherein the micro- or nanostructures are deposited on the portion of the first surface of the substrate with a transparency of at least 85%. Embodiment 66 is the method of any one of embodiments 61 to 65, wherein the micro- or nanostructures cover less than 50% of the first surface of the substrate or less than 30% of the first surface of the substrate. Embodiment 67 is the method of any one of embodiments 61 to 66, wherein the conductive material or conductive layer has a greater than 50% specular transmission or greater than 65% diffuse transmission. Embodiment 68 is the method of any one of embodiments 61 to 67, wherein the sheet resistance of the conductive layer or of the conductive material is less than 100Ω/□ or is less than 50Ω/□. Embodiment 69 is the method of any one of embodiments 61 to 68, wherein the conductive layer or the conductive material has a work function between 3.5 and 5.5 eV. Embodiment 70 is the method of any one of embodiments 61 to 69, wherein conductive material is a transparent electrode. Embodiment 71 is the method of embodiment 70, wherein transparent electrode has a surface roughness ranging from 5 nm to 50 nm rms. Embodiment 72 is the method of embodiment 71, wherein the incident radiation from the transparent electrode is from about 300 nm to 900 nm. Embodiment 73 is the method of any one of embodiments 70 to 72, wherein the transparent electrode is a flexible electrode. Embodiment 74 is the method of embodiment 70, wherein the transparent electrode is used as circuitry in flexible electronic circuits or transparent electronics or in a photovoltaic device. Embodiment 75 is the method of embodiment 70, wherein the transparent electrode is used as either an anode, a cathode, or both in a photovoltaic device. Embodiment 76 is the method of any one of embodiments 61 to 75, wherein the conductive layer has a surface modification layer deposited directly on it. Embodiment 77 is the method of any one of embodiments 61 to 76, wherein the conductive layer has an electron donating, an electron accepting or any combination thereof deposited directly on it, or directly deposited on the modification layer. Embodiment 78 is the method of any one of embodiments 76 to 77, wherein a second transparent electrode is deposited directly, or through the use of a surface modification layer, on top of the electron donor/acceptor combination. Embodiment 79 is the method of embodiment 70, wherein the transparent electrode is deposited on the top of an optoelectronic active layer which comprises an optically thick electrode, surface modification layers, electron donating and accepting materials or any combination thereof. Embodiment 80 is the method of embodiment 70, wherein the transparent electrode is the last component to be deposited on an organic photovoltaic (OPV) device fabricated on a reflective or opaque electrode. Embodiment 81 is the method of embodiment 70, wherein the transparent electrode is used as any component in a tandem solar cell or is used as a recombination layer in a tandem solar cell. Embodiment 82 is the method of embodiment 70, wherein the transparent electrode is used in a light emitting device. Embodiment 83 is the method of embodiment 82, wherein the light emitting device is a light emitting diode (LED) or an organic light emitting diode (OLED). Embodiment 84 is the method of embodiment 83, wherein the conductive film or transparent electrode is used as one or more electrodes in either a top emitting, or a bottom emitting organic light emitting diode (OLED). Embodiment 85 is the method of embodiment 83, wherein the conductive film or transparent electrode is used as one or more electrodes in a transparent emitting organic light emitting diode (OLED). Embodiment 86 is the method of embodiment 61, wherein the conductive material is used in a thin film transistor. Embodiment 87 is the method of embodiment 61, wherein the conductive material is used as a gate in a thin film transistor (TFT) or is used or is modified to be used as either a source or drain in a TFT. Embodiment 88 is the method of embodiment 61, wherein the conductive material is used as an electrode in read/write logic memory. Embodiment 89 is the method of embodiment 61, wherein the conductive material is used as an electrical bus in logic memory applications. Embodiment 90 is the method of any one of embodiments 1 to 60, wherein the conductive material is reflective or wherein the conductive material is a reflective electrode. Embodiment 91 is the method of embodiment 90, wherein the substrate is opaque or reflective. Embodiment 92 is the method of embodiment 90, wherein the substrate is transparent or opaque and the conductive layer is reflective. Embodiment 93 is the method of any one of embodiments 90 to 92, wherein the micro- or nanostructures are deposited via solution processing. Embodiment 94 is the method of any one of embodiments 90 to 93, wherein the substrate is a rigid substrate or is a non-flexible substrate. Embodiment 95 is the method of any one of embodiments 90 to 93, wherein the substrate is a flexible substrate. Embodiment 96 is the method of any one of embodiments 90 to 95, wherein the conductive layer covers at least 85% of the first surface of the substrate. Embodiment 97 is the method of any one of embodiments 90 to 96, wherein the sheet resistance of the electrode or of the conductive layer is less than 20Ω/□. Embodiment 98 is the method of any one of embodiments 90 to 97, wherein the specular reflection of the electrode or of the conductive layer is greater than 10% or the diffuse reflection is greater than 50%. Embodiment 99 is the method of any one of embodiments 90 to 98, wherein the conductive material or the conductive layer or the electrode has a work function between 3.5 and 5.5 eV. Embodiment 100 is the method of embodiment 90, wherein the conductive material is an electrode. Embodiment 101 is the method of embodiment 100, wherein the electrode is a flexible electrode. Embodiment 101 is the method of embodiment 90, wherein the conductive material or the electrode is used as circuitry in flexible electronic circuits. Embodiment 102 is the method of embodiment 90, wherein the conductive material or the electrode is used in a photovoltaic device. Embodiment 103 is the method of embodiment 90, wherein the conductive material or the electrode is used as an anode, a cathode or as both in a photovoltaic device. Embodiment 104 is the method of embodiment 90, wherein the conductive layer has a surface modification layer deposited directly on it. Embodiment 105 is the method of embodiment 90, wherein the conductive layer has an electron donating layer, an electron accepting layer or any combination thereof deposited directly on it, or directly on a modification layer. Embodiment 106 is the method of embodiment 90, wherein a conductive material or the electrode is deposited either directly or indirectly on top of an electron donor/acceptor layer combination. Embodiment 107 is the method of embodiment 90, wherein the conductive material or the electrode is deposited either directly or indirectly on top of an already existing donor/acceptor combination layer on a transparent electrode. Embodiment 108 is the method of embodiment 90, wherein the conductive material or electrode is used in a light-emitting device. Embodiment 109 is the method of embodiment 108, wherein the light-emitting device is a light emitting diode (LED) or an organic light emitting diode (OLED). Embodiment 110 is the method of embodiment 90, wherein the conductive material or electrode is used as an anode or cathode or combination of both in an organic light emitting diode (OLED). Embodiment 111 is the method of embodiment 110, wherein the organic light emitting diode (OLED) is built from the conductive material or electrode up. Embodiment 112 is the method of embodiment 90, wherein the conductive material or electrode is the last component to be built in an organic light emitting diode (OLED). Embodiment 113 is the method of embodiment 90, wherein the conductive material or electrode is used in a thin film transistor (TFT). Embodiment 114 is the method of embodiments 90, wherein the conductive material or electrode is used as a gate in a thin film transistor (TFT). Embodiment 115 is the method of embodiment 90, wherein the conductive material or electrode is used as the source, drain, or some combination thereof in a thin film transistor (TFT) through the use of surface modification. Embodiment 116 is the method of embodiment 90, wherein the electrode is used in read/write logic memory. Embodiment 117 is the method of embodiment 90, wherein the conductive material or electrode is used as an electrical bus in a logic memory device. Embodiment 118 is a conductive material made by the process of any one of embodiments 1 to 117. Embodiment 119 is the conductive material of embodiment 118, wherein said material is an electrode. Embodiment 120 is the conductive material of embodiment 119, wherein said electrode is a transparent electrode, a translucent electrode, an opaque electrode, or a reflective electrode.

In addition to the tunability of the process of the present invention to make transparent, opaque, and reflective conductive materials and electrodes, the work function of the conductive materials and electrodes can be tuned via the use of ligands. In particular, coating the nano- and micro-structures with specific ligands can vary or modify the work function of the resulting conductive materials and electrodes. By way of example, the work function of the conductive materials and electrodes of the present invention can be designed to have a work function of up to 8 eV, preferably from 1 to 8 eV, more preferably from 2 to 8 eV, or even more preferably from 3 to 6 eV. Notably, a given conductive material or electrode of the present invention can be designed to have a specific or targeted work function (e.g., 1, 1.5, 2, 2.5, 3, 3.5, 4, 4.5, 5, 5.5, 6, 6.5, 7, 7.5, or 8, or any non-integer therein). Non-limiting examples of ligands that can be used in the context of the present invention include polyvinylpyrrolidone (PVP), dodecanethiol (DDT), thiophenol, 1,6-hexanedithiol, 6-mercapto-1-hexanol, or 4-mercaptobenzoic acid (MBA), peptide functionalized nano- or micro-particles, or a combination thereof. Example 4 of the present specification provides data confirming the tunability of the work function of the conductive materials and electrodes produced by the processes of the present invention via the use of ligands.

Also disclosed in the context of the present invention is using a protective layer to protect the conductive layers, conductive materials, and electrodes produced by the processes of the present invention. The protective layer can help in protecting or limiting damage to the conductive layers, conductive materials, and electrodes during shipping or storage. For instance, the protective layers can help prevent or avoid nicks, scratches, or other physical damage to the conductive layers, conductive materials, and electrodes. Even further, the protective layers can help limit or prevent oxidation of the conductive layers, conductive materials, and electrodes. Non-limiting examples of such protective layers include thermoplastic films (e.g., polyethylene-based films, polypropylene-based films, polyester-based films, and blends thereof). Non-limiting examples of such films include polyethylene films, low-density polyethylene films, linear low-density polyethylene films, medium-density polyethylene films, high-density polyethylene films, ultra-high-molecular-weight polyethylene films, etc.

“Attach” or “attached” refers to the attachment or adhesion between the conductive micro- or nanostructure layer and the substrate's surface. In certain aspects, and after employing the process of the present invention, the conductive micro- or nanostructure layer is sufficiently attached to the surface of a substrate such that it is conductive after being subjected to the Scotch tape test or the bending test or both. The scotch tap test consists of firmly pressing by hand scotch tape to the produced conductive nanostructure layer and then peeling off said Scotch tape. The bending test consists of bending the produced conductive material around a rod having a radius of about 0.625 mm.

“Pre-conditioned” refers to the chemical or physical modification of the first surface of a substrate so as to increase the attachment between the substrate and the micro- or nanostructure material and resulting formed. An example of a chemical modification includes functionalizing the surface of the substrate with chemical groups to increase said attachment. An example of a physical modification includes the creation of recesses within the substrate's surface so as to attach or “grab” or “cling” to the nanostructures after the recesses are closed or removed such as by pressure or an adhesive material. Another example of physical modification includes the use of pressure on micro- or nanostructures that are disposed onto a substrate's surface prior to the simultaneous application of heat and pressure. The use of an adhesive can be in the form of a physical or chemical modification to the substrate's surface. For instance, the substrate can be prepared such that it has two layers, a base layer and an upper binding layer that includes adhesive material. Alternatively, the adhesive material can be disposed onto the surface of the substrate followed by disposing the micro- or nanostructures on the substrate or the micro- or nanostructures can be disposed onto the substrate surface followed by disposing the adhesive material onto said surface—in either event, the surface of the substrate can be said to be “pre-conditioned” so as to increase the attachment between the substrate and the conductive micro- or nanostructured layer. However, the substrate surface is not “pre-conditioned” when the micro- or nanostructures are coated with a film or polymer material that is used to help disperse or solubilize the micro- or nanostructures into a liquid prior to being disposed onto the surface of the substrate.

The transparency or translucency of a given object or medium (e.g., substrate, a conductive micro- or nanostructure layer, conductive material, etc.) can be determined by measuring the total transmittance of incident light through said object. As noted above, the reflectivity, translucency, or transparency of a conductive material produced by the process of the present invention can be controlled by the amount of micro- or nanostructures initial disposed on a substrate's surface. By way of example, the total transmittance of incident light through the produced conductive material can be 0%, 10%, 20%, 30%, 40%, 50%, 60% 70%, 80%, 90%, or more based, and this can be adjusted or tuned as desired based on the amount of micro- or nanostructures used in the process of the present invention. Further, and in instances where the substrate is transparent, more micro- or nanostructures may be used to create a sufficient reflectivity when compared with substrates that are translucent or that are opaque.

“Substrate” refers to a material onto which the conductive layer is attached. The substrate can be rigid or flexible. The substrate can be transparent, translucent, or opaque, or any degree of transparency, translucency, or opacity as desired. Non-limiting examples of rigid substrates include, for example, glass, polycarbonates, acrylics, etc. Non-limiting examples of flexible substrates include polyesters (e.g., polyethylene terephthalate, polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, etc.), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067. In instances where reflectivity is desired and the substrate is transparent or translucent, more micro- or nanostructures could be disposed onto the substrate's surface when compared with a substrate that is opaque. One reason for this is that the opacity or translucency of the substrate can contribute to the reflectivity when compared with a substrate that is transparent.

“Adhesive” refers to material that is used to bond two adjacent layers together (e.g., conductive layer and substrate). Examples of such adhesives include acrylic resins, chlorinated olefin resins, resins of vinyl chloride-vinyl acetate copolymer, maleic acid resins, chlorinated rubber resins, cyclorubber resins, polyamide resins, cumarone indene resins, resins of ethylene-vinyl acetate copolymer, polyester resins, urethane resins, styrene resins, polysiloxanes and the like, the matrices and polymeric matrices disclosed in WO 2012/063024 and U.S. Pat. No. 8,049,333, etc.

“Conductive nanostructured layer” refers to a network layer that comprises nanostructures that is capable of conducting electricity. “Conductive microstructured layer” refers to a network layer that comprises microstructures that is capable of conducting electricity. “Conductive micro- and nanostructure layer” refers to a network layer that comprises nanostructures and microstructures that is capable of conducting electricity. Since conductivity is achieved by electrical charge percolating from one micro- or nanostructure to another, a sufficient amount of micro- or nanostructures should be present in the conductive layer to reach an electrical percolation threshold and become conductive. The surface conductivity of the conductive micro- or nanostructure layer is inversely proportional to its surface resistivity, sometimes referred to as sheet resistance, which can be measured by known methods in the art.

“Nanostructure” refers to an object or material in which at least one dimension of the object or material is equal to or less than 100 nm (e.g., one dimension is 1 to 100 nm in size). In a particular aspect, the nanostructure includes at least two dimensions that are equal to or less than 100 nm (e.g., a first dimension is 1 to 100 nm in size and a second dimension is 1 to 100 nm in size). In another aspect, the nanostructure includes three dimensions that are equal to or less than 100 nm (e.g., a first dimension is 1 to 100 nm in size, a second dimension is 1 to 100 nm in size, and a third dimension is 1 to 100 nm in size). The shape of the nanostructure can be of a wire, a particle, a sphere, a rod, a tetrapod, a hyperbranched structure, or mixtures thereof.

“Microstructure” refers to an object or material in which at least one dimension of the object or material is equal to or less than 1000 microns and greater than 100 nm (e.g., one dimension is greater than 100 nm and less than 1000 microns in size). In a particular aspect, the microstructure includes at least two dimensions that are equal to or less than 1000 microns and greater than 100 nm (e.g., a first dimension is greater than 100 nm and less than 1000 microns in size and a second dimension is greater than 100 nm and less than 1000 microns in size). In another aspect, the microstructure includes three dimensions that are equal to or less than 1000 microns and greater than 100 nm (e.g., a first dimension is greater than 100 nm and less than 1000 microns in size, a second dimension is greater than 100 nm and less than 1000 microns in size, and a third dimension is greater than 100 nm and less than 1000 microns in size). The shape of the microstructure can be of a wire, a particle, a sphere, a rod, a tetrapod, a hyperbranched structure, or mixtures thereof.

The use of the word “a” or “an” when used in conjunction with the term “comprising” in the claims or the specification may mean “one,” but it is also consistent with the meaning of “one or more,” “at least one,” and “one or more than one.”

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

The term “substantially” is defined as being largely but not necessarily wholly what is specified (and include wholly what is specified) as understood by one of ordinary skill in the art. In any disclosed embodiment, the term “substantially” may be substituted with “within [a percentage] of” what is specified, where the percentage includes 0.1, 1, 5, and 10 percent.

Furthermore, a structure that is capable of performing a function or that is configured in a certain way is capable or configured in at least that way, but may also be capable or configured in ways that are not listed. Metric units may be derived from the English units provided by applying a conversion and rounding to the nearest millimeter.

The feature or features of one embodiment may be applied to other embodiments, even though not described or illustrated, unless expressly prohibited by this disclosure or the nature of the embodiments.

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The methods, ingredients, components, compositions, etc. of the present invention can “comprise,” “consist essentially of,” or “consist of” particular method steps, ingredients, components, compositions, etc. disclosed throughout the specification. With respect to the transitional phase “consisting essentially of,” in one non-limiting aspect, a basic and novel characteristic of the process of the present invention is that the surface of the substrates does not need to be pre-conditioned so as to achieve a sufficient attachment between the conductive micro- or nanostructure layer and the substrate's surface when heat and pressure are simultaneously applied to create said conductive micro- or nanostructure layer.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIG. 1. Scanning electron microscope (SEM) image of sprayed nanowires that resulted in a mesh after processing on PET substrate.

FIG. 2. Non-limiting illustration of preparing a material having a nanostructured conductive layer or mesh formed from processing the sprayed nanowires.

FIG. 3. Non-limiting illustration of a roll-to-roll process of the present invention.

FIG. 4A. SEM images of silver nanowires spray coated onto a PET substrate at 60° C. without rolling at 5 μm, 1 μm, and 500 nm.

FIG. 4B. SEM images of silver nanowires spray coated onto a PET substrate and rolled at 60° C. at 5 μm, 1 μm, and 500 nm.

FIG. 4C. SEM images of silver nanowires spray-coated onto a PET substrate at 60° C. and rolled at 165° C. at 5 μm, 1 μm, and 500 nm.

FIG. 5A. AFM images of silver nanowire mesh sprayed at 60° C. on a PET substrate at 2 μm.

FIG. 5B. AFM images of silver nanowire mesh sprayed at 60° C. on a PET substrate and rolled at 60° C. at 2 μm.

FIG. 5C. AFM images of silver nanowire mesh sprayed at 60° C. at 60° C. on a PET sprayed and rolled at 165 C at 2 μm.

FIG. 6. Comparison of the conductivity of the silver nanowire meshes against the temperature at which they were rolled. All spraying of the initial silver nanowire meshes on PET was carried out at 60° C. The data shown is the result of a minimum of 10 measurements taken randomly across each sample

FIG. 7A. SEM images at 1 μm of silver nanowire meshes on PET substrates rolled at 50 psi at a speed of 10 cm/s.

FIG. 7B. SEM images at 1 μm of silver nanowire meshes on PET substrates rolled at 50 psi at a speed of 1 cm/s.

FIG. 7C. SEM images at 1 μm of silver nanowire meshes on PET substrates rolled at 250 psi at a speed of 10 cm/s.

FIG. 7D. SEM images at 1 μm of silver nanowire meshes on PET substrates rolled at 250 psi at a speed of 1 cm/s.

FIG. 8. Sheet resistance versus bending of a sample around a given radius of curvature for as-sprayed silver nanowire samples on PET, and silver nanowire meshes rolled at 165° C. The inset shows data for the sheet resistance of each sample after the specified number of bending cycles at a radius of curvature of 1 mm. Each data point is the result of 5 measurements across each sample.

FIG. 9. Normal and total transmission profiles of the PET substrate, the as-sprayed silver nanowires on PET, and the nanowires on PET that were rolled at 165° C. The asterisk (*) indicates the silver nanowires were rolled.

FIG. 10. I-V curves for transparent electrode/PEDOT:PSS/P3HT:PC₆₁BM/LiF/Al OPV cells, where the transparent electrode is ITO, or silver nanowires on PET (Ag NWs). The asterisk (*) refers to testing procedure where a reverse bias is applied before testing.

FIG. 11A. SEM images at 500 nm of cross-sectioned of a PEDOT:PSS/PET electrode of model OPV devices of the aluminum top electrode and the layers corresponding to an underlying PEDOT:PSS on a PET substrate.

FIG. 11B. SEM images at 500 nm of cross-sectioned of a PEDOT:PSS/PET electrode model OPV devices based with as-sprayed silver nanowire mesh on PET.

FIG. 11C. SEM images at 500 nm of cross-sectioned of a PEDOT:PSS/PET electrode model OPV devices with rolled silver nanowires.

FIG. 12A Normal reflection data of conductive nanowire layers on PET substrates as deposited (dashed lines) and as processed (solid lines) with heat and pressure.

FIG. 12 B. Total reflection data of conductive nanowire layers on PET substrates as deposited (dashed lines) and as processed (solid lines) with heat and pressure.

FIG. 13. SEM image of reflective electrode as Ag nanowires (NWs), at a concentration of 5 mg/ml rastered 20 times, deposited on PET substrate.

FIG. 14A. 14A. SEM images of reflective electrode as processed at 165° C. and pressure 50 psi at 5 μm magnification scale.

FIG. 14B. SEM images of reflective electrode as processed at 165° C. and pressure 50 psi at 20 μm magnification scale.

FIG. 15. Structure and name of ligands used for electrode work-function tuning.

FIG. 16. XPS spectrum of the oxygen is peak of silver nanowires, with both the PVP and DDT ligands. Circles represent the raw data.

FIG. 17. XPS spectra of the sulfur feature on nanowires with a PVP ligand, and a dodecanethiol ligand.

FIG. 18. Ultraviolet photoelectron spectroscopy (UPS) of silver nanowires with different ligand functionalization.

### DETAILED DESCRIPTION OF THE INVENTION

While conductive micro- or nanostructure layers on substrates (e.g., nanostructured layers such as silver nanowire meshes) are promising due to the potential for the scale-up necessary for mass-manufacturing, there are a number of challenges associated with their use, most notably topological roughness that leads to short-circuits (shunts) between the two electrodes (Lee, et al., 2008), and poor adhesion to the underlying electrode (Angmo & Krebs, 2013; De, et al., 2009). As discussed above, there have been attempts to address the adhesion problems by using pre-conditioning steps that can be costly, time-consuming, and potentially detrimental to the resulting conductivity of the electrode.

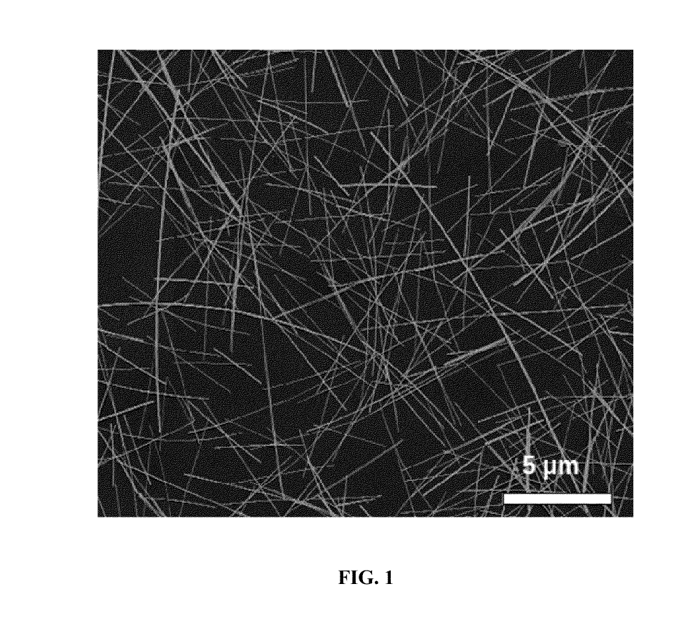

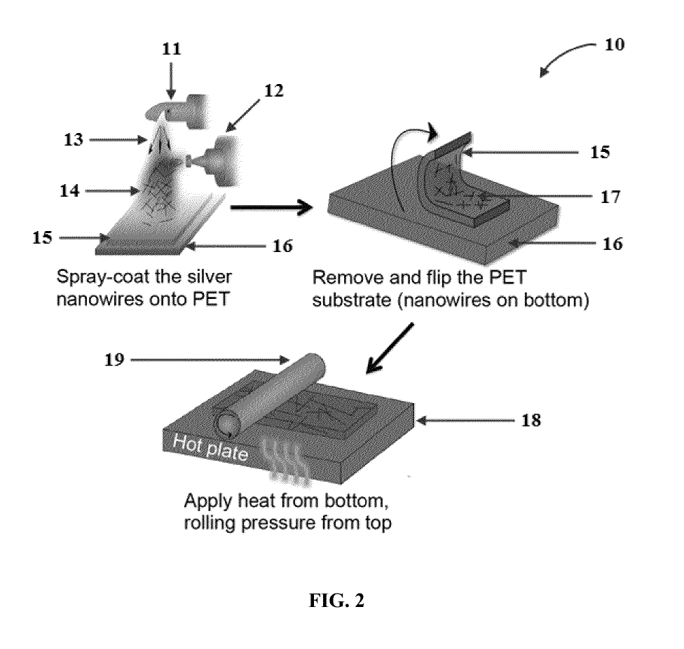

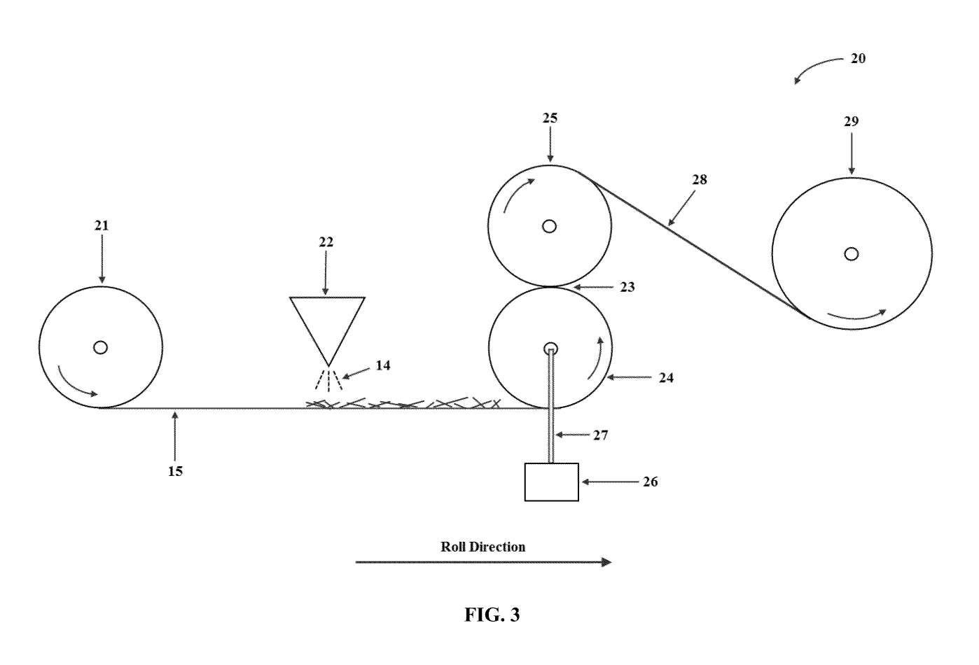

A solution to the current problems facing the production of micro- or nanostructured conductive layers has been discovered. This solution resides in the simultaneous application of heat and pressure without the need for a pre-conditioning step, thereby resulting in a cost efficient and scalable process for producing conductive materials that can be used in a wide range of applications and electronic devices. The solution also provides a way to transform a transparent or translucent substrate into a reflective conductive material by varying the amount of micro- or nanostructures used, varying the amount of pressure used (e.g., varying the roller pressure), varying the temperature/heat used, and/or (d) varying the type or types of micro- or nanostructures. These same parameters can also be used to selectively tune the sheet resistance of the resulting electrodes produced by the processes of the present invention. In this sense, the solution provides for a way to “tune” the reflectivity and sheet resistance of a given electrode by simple processing parameters. Further, and in view of the fact that the same type of substrate can be used in the production process for both reflective and transparent electrodes, the same equipment can be used for producing any of the electrodes of the present invention. This has the added advantage of reducing capital costs, operator training (interchangeable operators), and limit the spatial requirements needed by using one production line rather than multiple production lines to produce a wide variety of electrodes of the present invention. Therefore, transparent, translucent, and opaque substrates can be used in the context of the present invention. These and other non-limiting aspects of the present invention are discussed in detail below with reference to FIG. 1, FIG. 2, and FIG. 3.

FIG. 1 is a scanning electron microscope (SEM) image of sprayed nanowires that resulted in a mesh after processing on a PET substrate. FIG. 2 illustrates in a non-limiting way the process by which the nanowires are sprayed onto a substrate such as PET and then further processed with simultaneous application of heat and pressure to form a mesh. Referring to FIG. 2, an ultra-sonic spray coating system (such as the Sono-Tek ExactaCoat^{sc} system) is illustrated that has an air nozzle (11) that produces an air stream (13) and a spray nozzle (12) that sprays a micro or a nanostructure composition (14) (or a composition that includes a mixture of microstructures and nanostructures or at least two compositions, in which the first includes microstructures and the second includes nanostructures) onto the first surface of a substrate (15) via the air stream (13). The substrate (15) (which can be transparent, translucent, or opaque) can be supported by a support material (16) (e.g., any material can be used so long as it physically supports the substrate as it is being sprayed with the micro- or nanostructure composition (14)). As discussed above, however, other methods of disposing the micro- or nanostructure composition (14) onto the substrate (15) are contemplated (e.g., spray coating, role-to-role coating, ink jet printing, screen printing, drop casting, spin coating, dip coating, Mayer rod coating, doctor blade coating, etc.). The amount of the micro- or nanostructure composition (14) disposed onto the substrate surface (15) can be adjusted via the air nozzle (11) and spray nozzle (12), which can be used to tune or select a given reflectivity, translucency, or transparency of the resulting conductive micro- or nanostructure layer. Additionally, the sheet resistance of the resulting electrode can be tuned by any one of or any combination of the following parameters: (a) varying the amount of the micro- or nanostructure composition (14) deposited on the substrate surface (15); (b) varying the amount of pressure used (e.g., varying the roller pressure); (c) varying the temperature/heat; and/or (d) varying the micro- or nanostructure type or types being used. The micro- or nanostructure composition (14) can include micro- or nanostructure dispersed or dissolved in a liquid medium or solvent (e.g., aqueous solvents, alcohols, polar hydrocarbons, chlorinated solvents, combinations thereof). In order to increase the dispersibility or solubility of the micro- or nanostructures (17) in the liquid medium or solvent, the micro- or nanostructures (17) can be coated with an organic polymeric ligand that includes, for example, a thiol, a phosphorus, or an amine group or combinations thereof (e.g., polyvinylpyrrolidone or polyphenylene vinylene or a combination thereof). As discussed in the Examples, the micro- or nanostructure composition (14) can be made by mixing desired microstructure or nanostructures or both (17) with the liquid medium. After the micro- or nanostructure (17) composition (14) is disposed on the substrate surface (15), the composition (14) can be allowed to dry to remove the liquid or solvent material, such as by air drying or heat drying. Drying can be carried out quickly (e.g., less than 1 minute), to avoid re-dissolving the micro- or nanostructure (17). This may be done in-situ, for example, by applying heat from the support (16) or as a secondary process. Alternatively, and if so desired, one can choose to skip such a drying step. The substrate (15) having the micro- or nanostructures (17) can then be flipped over to have the micro- or nanostructure (17) come into direct contact with a heat source (18). In the FIG. 2 embodiment, the heat source (18) directly contacts the disposed micro- or nanostructures (17) such that the micro- or nanostructures (17) are in between the heat source (18) and the substrate's (15) surface. However, in other aspects, the heat source (18) can directly contact both the micro- or nanostructures and the substrate's (15) surface. The heat source (18) can be a standard hot plate as shown in FIG. 2 that is capable of directly (e.g., direct contact with the substrate's (15) surface) or indirectly (e.g., through contact with the micro- or nanostructures (17)) heating the entire surface area of the substrate (15). By having a stationary heat source (18), application of a pressure source (19) on the opposite side of the substrate (15) can be used, thereby providing for simultaneous application of heat and pressure to the micro- or nanostructures. While the heat source (18) can be “turned on” at any point in the process, it is the application of both heat and pressure at the same time that allows for sufficient attachment of the micro- or nanostructures (17) to the substrate (15). The heat source (18) can be used to heat the micro- or nanostructures (17) or the surface of the substrate (15) that is carrying the nanostructures (17) to a temperature that is greater than the glass transition temperature or the Vicat softening temperature of the substrate (15) and less than the melting point of the substrate (15). A person having ordinary skill in the art would be able to readily determine these temperatures by referring to reference manuals or by performing well-known assays (e.g., Vicat softening point is a standardized test that is used to determine the temperature at which a material is penetrated to a depth of 1 mm by a flat-ended needle with a 1 mm² circular or square cross-section—for the Vicat A test, a load of 10 N is used; for the Vicat B test, the load is 50 N.). By way of example, the glass transition temperature (Tg) of PET is approximately 70° C., while its Vicat B softening temperature is approximately 82° C., and its melting point is about 260° C. Table 1 below provides non-limiting substrates (and the respective glass transition and Vicat softening temperatures) that can be used in the context of the present invention The pressure source (19) illustrated in FIG. 2 is a standard stainless steel metal roller/cylindrical bar. Any type of roller (e.g., metal rollers, rubber rollers, composite rollers, plastic rollers etc.) with any degree of hardness (e.g., 40, 50, 60, 70, 80, 90 points on the Shore A scale) provided that a sufficient amount of pressure can be applied to attach the micro- or nanostructures (17) to the substrate surface (15). As explained above and in the examples, the scotch tape test or bending test can be used to determine whether sufficient attachment is achieved. In particular embodiments, the pressure applied by the pressure source (19) can be between 25 to 300 psi or 50 to 250 psi or 75 to 200 psi, and if a roller is used, the roller can move across the opposite surface of the substrate (15) at a rate of at least 0.1 cm/s up to 100 cm/s or at a speed of 0.5 to 12 cm/s or at a speed of 1 to 10 cm/s. In other embodiments, the pressure source (19) can be an opposing plate or other object that can be used to squeeze the substrate (15) between the heating source (18) and the pressure source (19).

FIG. 3 represents yet another embodiment by which conductive materials can be processed in accordance with the methods of the present invention. In particular, FIG. 3 illustrates a non-limiting roll-to-roll system (20) that can be used to produce reflective, opaque, or transparent electrodes of the present invention. The opacity, reflectivity, and transparency as well as the sheet resistance of the electrodes can be tuned or modified as desired without having to switch out the equipment or materials used in the system (20). The tuning parameters include varying the amount of micro- or nanostructures used (e.g., an increase in reflectivity and opacity and a decrease in sheet resistance can be obtained by using more micro- or nanostructure material), varying the amount of pressure used (e.g., increased pressure can flatten out the micro- or nanostructures, thereby providing for more coverage of the surface area of the substrate and thus increasing the reflectivity and opacity and decreasing the sheet resistance of the resulting electrode), varying the temperature/heat used (e.g., increased heat can result in the micro- or nanostructures becoming deeply embedded into the substrate layer as well as increasing the likelihood that these structures flatten out more under pressure, thereby providing for more coverage of the surface area of the substrate and thus increasing reflectivity and opacity as well as decreasing sheet resistance of the electrode), and/or (d) varying the type of micro- or nanostructures (e.g., larger structures can increase the coverage area of the substrate surface, thereby increasing reflectivity and opacity and decreasing sheet resistance of the electrode). The system (20) includes a supply roll (21) that provides the substrate (15) to be treated with the micro- or nanostructure composition (14). Downstream from supply roll (21) is a depositing system (22) (e.g., an ultra-sonic spray coating system such as the Sono-Tek ExactaCoat^{sc} system) that is used to deposit the micro- or nanostructure composition (14) onto an exposed surface of the substrate (15). The depositing system (22) can be set to deposit a selected amount of the micro- or nanostructure composition (14) on the substrate (15) surface to produce reflective, opaque, or transparent electrodes (28) as well as to produce a selected or targeted sheet resistance of the electrodes (28). The coated substrate (15) is then passed through a nip (23) that is between a heated idler roller (24) and a drive roller (25). A pneumatic cylinder (26) is connected via a rod (27) to the axle of the heated idler roller (24) to maintain a desired pressure on the coated substrate (15) when passing through the nip (23). The heat of the roller (24) and the pressure applied can each be set to achieve a particular transparency, opacity, or reflectivity of the produced electrode (28) as well as a selected or targeted sheet resistance of the produced electrode (28). In passing over the surface of the heated idler roller (24), the substrate (15) surface coated with the composition (14) is heated to a temperature that is greater than the glass transition temperature or the Vicat softening temperature of the substrate (15) and less than the melting point of the substrate (15) as it passes through the nip (23), the temperature being below the melting temperature of micro- or nanostructures in the composition (14). The simultaneous application of heat and pressure allows for the micro- or nanowire structures to sufficient adhere to the substrate (15) and form a mesh or web of interconnected structures, thereby producing an electrically conductive material such as an electrode (28). As the electrode (28) leaves the drive roller (25) it is collected onto a take-up roll (29). In an alternative embodiment, the drive roller (25) can also be heated, thereby providing heat to both surfaces of the substrate (15). In still another embodiment, the drive roller (25) can be heated and the idler roller (24) is not heated, thereby providing heat to the back surface of the substrate (15) that does not include the micro- or nanowire structure composition (14). Still further, the positions of the idler roller (24) and the drive roller (25) can be switched such that the idler roller (24) comes into direct contact with the back surface of the substrate (15) and the drive roller comes into direct contact with the front surface of the substrate (15) that has the composition (14) deposited on the front surface. Also, the produced electrode (28) can then be feed into another roll-to-roll process to provide a protective layer for the electrode (28) during shipping or storage. As noted elsewhere, non-limiting examples of protective layers include polyethylene films, low-density polyethylene films, linear low-density polyethylene films, medium-density polyethylene films, high-density polyethylene films, ultra-high-molecular-weight polyethylene films, etc.

TABLE 1

| | Glass | | |
|---|---|---|---|
| | transition | Melting | Vicat B at |
| | temperature | point | load of |
| Polymer Name | (Tg) ° C. | (Tm) ° C. | 50 N ° C. |
| Polyethylene terephthalate (PET) | 70 | 260 | 82 |
| Polycarbonate (PC) | 147 | 155 | 145 |
| Polybutylene terephthalate (PBT) | 68 | 223 | 120 |
| Poly(1,4-cyclohexylidene | 70 | 225 | 120 |
| cyclohexane-1,4-dicarboxylate) | | | |
| (PCCD) | | | |
| Poly(phenylene oxide) (PPO) | 215 | 262 | 120 |
| Polypropylene (PP) | −20 | 170 | 108 |
| High density polyethylene (HDPE) | −90 | 130 | 128 |
| Polyvinyl chloride (PVC) | 100 | 170 | 80 |
| Polystyrene (PS) | 100 | 240 | 161 |
| Polymethylmethacrylate (PMMA) | 110 | 160 | 145 |
| Polyethyleneimine (PEI) | 215 | 380 | 125 |
| Terephthalic acid (TPA) elastomers | 425 | 500 | — |
| Glycol modified polycyclohexyl | −3 | 207 | 170 |
| terephthalate (PCTG) | | | |
| Thermoplastic elastomer (TPE) | 75 | 235 | 90 |
| poly(cyclohexanedimethylene | 90 | 274 | 110 |
| terephthalate) (PCT) | | | |

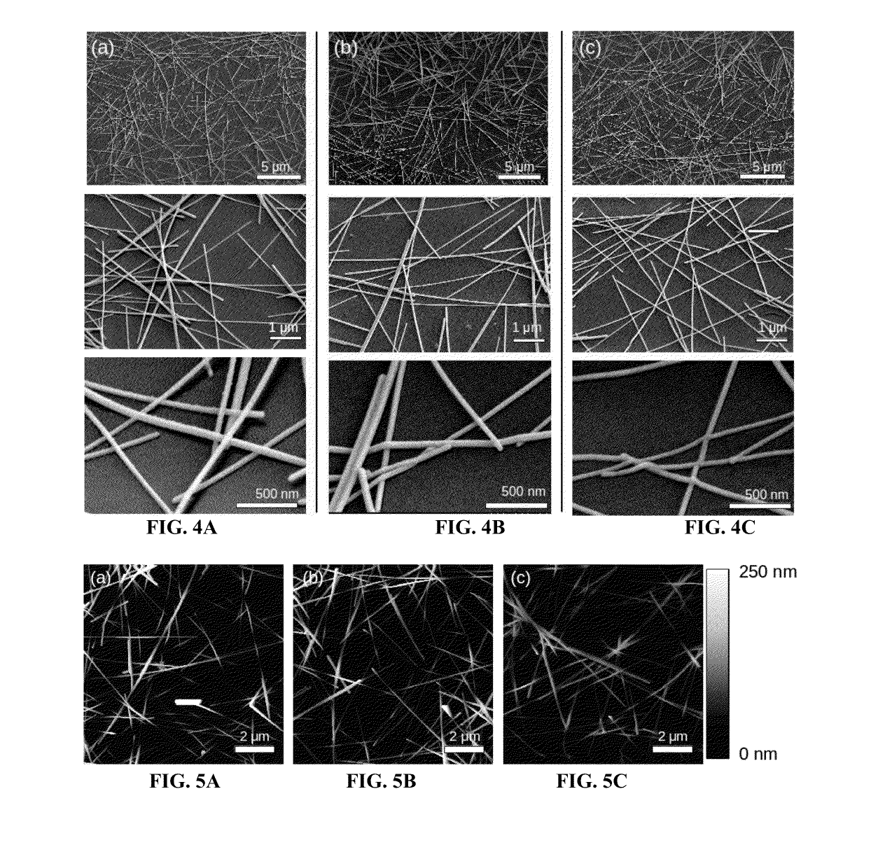

Without wishing to be bound by theory, the inventors suspect that the simultaneous application of heat and pressure allows for a plurality of the micro- or nanostructures to become embedded into the upper surface layer of the substrate (15) while also allowing the micro- or nanostructures to form junctions with one another, thereby creating a conductive matrix or layer that is sufficiently attached to the substrate (15) and that has a sufficiently low surface roughness. This procedure can be done without the need for any pre-treatment steps of the surface of the substrate (15), thereby providing a more convenience, cost-efficient, and scalable process when compared with those currently being used in the art. FIGS. 4 and 5 represent this and are discussed in detail below.

The conductive materials of the present invention can be used in a wide range of applications and electronic devices. Further, the fact that this process can be used to produce both reflective and transparent or translucent conductive materials such as electrodes from the same substrate further illustrates the scope to which the disclosed process can be used. Even further, the process of the present invention can be used to create both the upper and lower electrodes for a single device or can be used to create cathodes and anodes for a single device. By way of example only, the conductive materials of the present invention can be incorporated into a wide variety of devices, including any device that currently makes use of transparent conductors (such as metal oxide films) or reflective conductors or both. For instance, the following devices are contemplated: (i) Electronic display devices including an electroluminescent (EL) device (e.g., an organic light emitting display (OLED)), an electrophoretic display (e-paper), an electrochromic device, a liquid crystal display device (e.g., transflective liquid crystal display (LCD) devices) or an electrowetting display device; (ii) Photovoltaic cells, for instance amorphous silicon (a-Si) cells; (iii) Light irradiation devices and decorative illumination devices, for instance, devices containing light-emitting elements such as light-emitting diodes and semiconductor lasers; (iv) Electromagnetic radiation shield devices; (v) Any device which requires a reflective electrode; and (vi) Electronic device e.g photovoltaic cells, a transistor, a resistor, a logic device, sensors, antennas, integrated circuits, electroluminescence devices, memory elements or a field effect device.

### EXAMPLES

The present invention will be described in greater detail by way of specific examples. The following examples are offered for illustrative purposes only, and are not intended to limit the invention in any manner. Those of skill in the art will readily recognize a variety of noncritical parameters, which can be changed or modified to yield essentially the same results.

### Example 1

### Materials and Methods for Transparent/Translucent Electrodes

Materials.

100 micron-thick PET film substrates were provided by SABIC; the T_{g} of the PET film was reported to be 75° C. Lithium fluoride (LiF), silver chloride (AgCl), potassium bromide (KBr), silver nitrate (AgNO₃), polyvinylpyrrolidone (PVP) and ethylene glycol were purchased from Sigma Aldrich and used without any further purification. Solvents were purchased from available commercial sources and used as received unless mentioned otherwise. Aluminum was received in pellets from Kurt J. Lesker. For the active layer of the OPV devices, the PC₆₁BM and P3HT were purchased from American Dye Source and Reike Metals Inc., respectively. PEDOT:PSS (PVP AI 4083) was purchased from Heraeus. ITO was purchased from Delta Technologies and had a sheet resistance of 8-12Ω/□. Before organic photovoltaic device fabrication the ITO was cleaned with successive 10 minute sonication steps in methylene chloride, deionized water, and IPA, followed by a 10 minute exposure to an air plasma with a base pressure of 0.8-1 torr.

Synthesis of Silver Nanowires.

Silver nanowires were synthesized following literature procedures with slight modifications to the reaction time and purification procedures (Hu et al. (2010); Sun et al. (2002); Lee et al. (2008)). A typical synthesis involves reaction of a mixture of 1.32 g polyvinylpyrrolidone (PVP, average molecular weight 55,000) and KBr (0.040 g, 0.034 mmol) in 75 mL ethylene glycol heated at 173° C. in a pear shaped three necked flask for 90 min with constant magnetic stirring (˜1200 rpm). After attaining a stable solution temperature, finely ground AgCl (0.21 g, 1.40 mmol) was added to the mixture to initiate nucleation of the silver seeds. After about 5 min, a solution of AgNO₃ (0.88 g, 5.18 mmol in 8 mL of ethylene glycol) was added to the reaction mixture over 15 min. Afterwards, the resulting mixture was heated at 173° C. for an additional 4 h and then allowed to settle at room temperature for 72 h. During this period, the silver nanowires precipitated at the bottom of the flask while other various shapes of micro- or nanostructures such as cubes, rods and spheres remained in the supernatant and were decanted from the reaction flask. The remaining silver nanowire precipitate was then dispersed into 70 mL of methanol and centrifuged twice at 2500 rpm for 40 min to remove ethylene glycol, PVP and other impurities. Finally, uniform silver nanowires were dispersed in 30 mL of methanol.

Ligand Exchange Procedures.

The ligand was dissolved in an appropriate solvent (Methanol (MeOH)) at a concentration of 4 times excess to total silver nanowires in suspension (18.7 mM). The volume of solution was the same as the original nanowire suspension. If ligand was a liquid material in this case it was used neat, or diluted with MeOH to 18.7 mM. First, centrifuge original silver nanowire solution (4.7 mM, 0.5 mg/ml) for 2 min at 4400 rpm in a 50 mL centrifuge tube then decant the solvent. Then add new ligand solution to the centrifuge tube containing the condensed silver nanowires. This suspension was shaking or vortex until wires became dispersed in the solvent. To have a better dispersion and effective ligand exchange, the nanowires may be sonicated for a brief time (10-20 seconds) as longer sonication times will start to damage the nanowires. The suspension was left alone for approximately 2 h to ensure that the nanowires remained in suspension. The centrifuge tube was shaken periodically to re-suspend any nanowires that fell out of suspension. After 2 h, centrifuged the nanowires for 2 minutes at 4400 rpm again and decant solvent. Redisperse the wires in appropriate solvent to store and use them.

Silver Nanowires Mesh Preparation.

Before processing, the PET substrates were cleaned by rinsing in a 1:1 acetone/IPA mixture for approximately 5 s, wiping with a Kimtec kimwipe, rinsing again with the acetone/IPA, and then blown dry with nitrogen. All spray-coating was carried out using a Sono-Tek ExactaCoat SC ultra-sonic spray coating system in an ambient atmospheric environment. For all samples the ultra-sonic tip vibrated at 60 kHz with a power of 1.0 W at a height 55 mm above the sample, which rested on a heated plate. The temperature of the heated plate was set to the desired temperature before spraying and allowed to stabilize. A 5 mg/ml solution concentration was used for all samples with a solution flow rate of 800 μl/min. Argon at a set pressure of 17 kPa was used as flowing gas to control the shape of the deposited film. The nozzle was rastered over the entire length of a substrate horizontally at a speed of 50 mm/s and offset 4 mm perpendicularly to the substrate between passes. Upon completion of 1 full raster cycle, the pattern was repeated but shifted perpendicularly 2 mm on each pass to ensure a uniform film. When both raster patterns were completed, the coated PET was removed from the spray coating system and placed on a polished stainless steel hot plate face down at the desired temperature. A stainless steel roller was then rolled on the back of the PET. The rolling process was carried out six times to ensure that the whole substrate had been processed with an equal amount of pressure. The substrates prepared for these experiments ranged in size from a length of 75 to 150 mm and a width of 15±2 mm.

Assembly of the P3HT/PC₆₁BM OPV Devices.

In a nitrogen-filled glove box, 25 mg of P3HT and PC₆₁BM were placed in separate vials followed by addition of 500 μl of o-dichlorobenzene to each vial. After stirring on a hot plate at 80° C. overnight, the PC₆₁BM solution was added to the P3HT solution and allowed to stir for 2 h in the glove box before being removed for spin coating in air. The resulting solution was 1:1 w/w of P3HT:PC₆₁BM solution with a concentration of 25 mg/ml of each constituent. On every transparent electrode (ITO or silver nanowire mesh), a PEDOT:PSS layer was spin cast in air at 4000 rpm for 60 s, followed by the active layer that was spin-coated at 600 rpm for 60 s. The active layer film was allowed to dry in a plastic petri dish until the film changed from an orange to purple color. Upon drying, the film was loaded into the glove box which was pumped down to a base pressure of 5×10⁻⁶ mbar for thermal evaporation of the LiF (0.8 nm) and Al (80 nm) top electrode. During OPV testing many of the unprocessed samples had a low shunt resistance possibly due to shorting caused by the nanowires. A negatively applied bias ranging from −1 V to −5 V was put across the two electrodes. This tended to increase the shunt resistance.

Characterization.

Sheet resistance was measured using a Keithley 2400 source meter in conjunction with a Jandel 4 point probe unit, and values reported are taken to be the average of a minimum of 8-10 measurements from random parts of the substrate unless otherwise stated. UV-vis spectra were taken on a Perkin Elmer Lambda 900 Spectrophotometer operated in normal mode. For diffuse transmission measurements, the same UV-vis spectrometer was used with an integrating sphere and an incident beam at a normal angle to the surface of the substrate. All transmission data has been corrected for the PET substrate. Atomic Force Microscopy (AFM) was performed in tapping mode on a Digital Instruments/Veeco multi-mode tapping AFM. The collected data was analyzed using the open source software, Gwyddion. Scanning Electron Microscopy (SEM) images were taken using a Hitachi S4800 high resolution microscope with a beam current of 20 μA and an accelerating voltage between 1 and 15 kV. Samples on PET had a thin layer (5 nm) of gold sputtered on top to assist with imaging. Pressure was determined using a Fujifilm Prescape tactile pressure indicating film at room temperature. Keeping the substrate width constant and using only the weight of the pin allowed for reproducible pressure applicability. The higher pressure was estimated by pushing on the pin with approximately 4 times the weight of the roller. OPV performance was evaluated using custom designed software to interface with a Keithley 2400 source meter and an OAI Trisol 300 W AAA solar simulator. The light intensity was set against a Si reference cell from PV Measurements Inc, Model number PVM624, fitted with a KG5 filter. This calibration was carried out at the beginning of each test. X-ray photoelectron spectroscopy (XPS) and ultraviolet photoelectron spectroscopy (UPS) measurements were both carried out by using Kratos Axis Ultra. UPS measurements were performed using the He I (21.21 eV) UV radiation. UPS samples were biased at −10V for secondary electron measurements. The resulting data was fit to a straight line. Work function measurements are reported as the intercept of this line with the x-axis. XPS was carried out using an Al Kα X-ray source (1486.6 eV), with a sample take off angle of 90°. XPS data was analyzed using the software CasaXPS. Peak locations were not constrained during fitting. Samples for XPS and UPS were prepared in an identical manner. Namely, a solution of nanowires functionalized with the appropriate ligand was drop cast onto a piece of silicon in air. The silicon was cleaned via sonication in a solution of Isopropyl alcohol and acetone at a 50:50 mix.

### Example 2

### Results for Transparent/Translucent Electrodes

Produced Conductive Materials:

Silver nanowires with diameters of 50-100 nm, and lengths of 5-10 microns were prepared via a straightforward solution phase procedure (Hu, et al., 2010). A representative example of a spray-coated silver nanowire mesh on PET is shown in the scanning electron microscope (SEM) image in FIG. 1. The commercial PET films from SABIC were 100 microns thick, with a reported T_{g} of 75° C. and a Vicat softening temperature of 79° C. and 75° C. for the Vicat A and Vicat B tests respectively. FIG. 2 provides the schematic outline of the electrode processing described: the silver nanowires were spray-coated onto cleaned PET, removed from the spray-coater, and turned over onto a polished stainless steel hot plate with the nanowires in contact with the hot plate surface at the desired temperature. The back of the PET film was then rolled with a stainless steel rod (radius=30 mm), and then removed and allowed to rapidly cool. If not stated, the stainless steel rod was passed over the substrate six times at a speed of 10 cm s⁻¹ at a measured pressure of 50 pounds per square inch (psi). The electrodes were then analyzed through a variety of techniques, including SEM and AFM, transmission and conductivity measurements, bending tests, and finally incorporation into OPV devices.

Examples of silver nanowire meshes on PET substrates are shown in the low-, medium-, and higher-resolution SEM images in FIGS. 4A-C A silver nanowire solution that was sprayed but had no further treatment can be seen in FIG. 4A, and it appears that the rigid rods/wires overlap, with some not in obvious physical contact with the underlying PET. In FIG. 4B, rolling the wires on the surface heated to 60° C. results in some flattening of the wires with respect to the substrate surface, but no obvious welding at nanowire junctions. At a higher temperature, 165° C., as shown in FIG. 4C the nanowires have welded together at their intersection points. AFM images of the samples in FIGS. 4A-C are shown in FIGS. 5A-C; the sample roughness rms value for the unrolled silver nanowires is 43 nm (FIG. 5A), for the nanowires rolled 60° C. it is 36 nm (FIG. 5B), and for the nanowire sample rolled at 165° C. it is 27 nm (FIG. 5C), clearly showing a decrease in topological roughness of these samples after rolling.

Effect of Temperature, Pressure, and Rolling Speed:

Table 2 shows the results for spray-coated silver nanowire mesh electrodes, prepared on both glass and PET substrates; the nanowires were deposited in an identical manner in all cases (800 μl/min, 60° C., 2 passes, 5 mg/ml).

TABLE 2

| | Sheet |
|---|---|
| Substrate | resistance (Ω/□) |
| Glass | 2400 ± 1020 |
| Glass, rolled at 165° C. | 484 ± 202 |
| PET | 5800 ± 1200 |
| PET, rolled at 165° C. | 17.5 ± 2.2 |
| PET, annealed at 165° C. | 174 ± 133 |

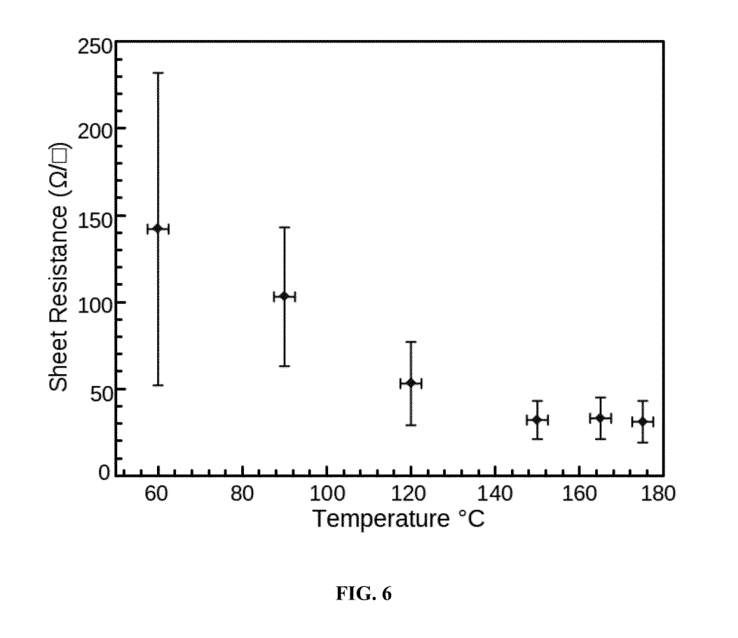

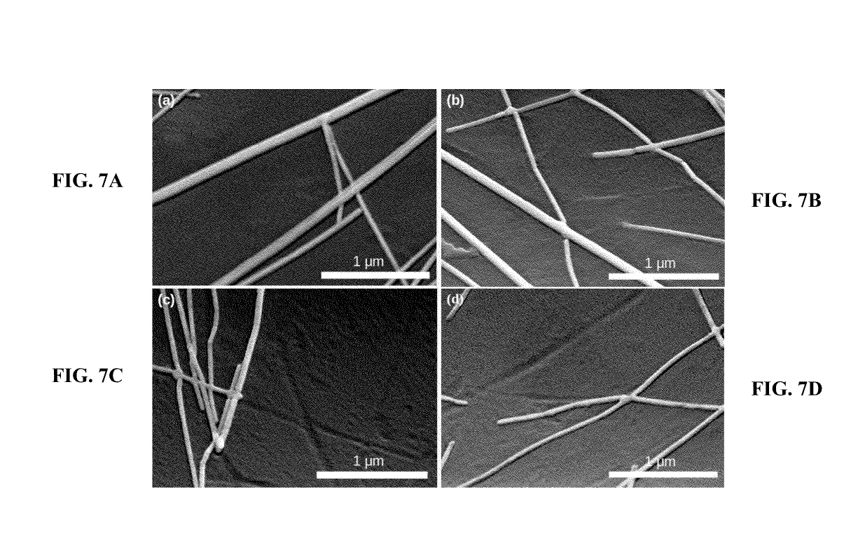

The silver nanowires on glass or PET with no rolling or annealing are highly resistive, with measured sheet resistances of 2400 and 5800Ω/□, respectively. Rolling the silver nanowires on glass at 165° C. results in a drop of sheet resistance by about an order of magnitude, but it is on PET that the effects are most obvious. On PET, rolling at 165° C. leads to an observed drop in sheet resistance to 17.5±2.2Ω/□. The sheet resistance for the nanowire mesh on PET placed face-down on the hot plate at 165° C. for the same length time, without rolling, is 174±33Ω/□, about an order of magnitude greater than that of the rolled sample, keeping the temperature constant. As summarized in FIG. 6 for silver nanowires on PET, the sheet resistances drops with an increase in temperature at which the hot plate is held while the sample is rolled. More importantly from a manufacturability perspective, the standard deviation for the measured sheet resistances drops substantially as rolling temperatures increase; above a rolling temperature of 150° C., the sheet resistance is consistently below 50Ω/□, whereas at a lower temperature of 60° C., the sheet resistance varies much more dramatically, from just over 50Ω/□ to 230Ω/□. This can be explained by the softening of the substrate allowing for any deviation in substrate thickness to be negated by the force of the roller. Once the substrate is sufficiently soft all of the micro- or nanostructures have an equal force applied to them from the roller. These welding results are in line with prior literature results where temperatures in excess of 150° C. are typically required to anneal the silver nanowire junctions (Garnett, et al., 2012; Madiara, et al., 2010).

The influence of speed and pressure on the sheet resistance is subtle and can be seen in Table 3.

TABLE 3

| | | | Sheet resistance |
|---|---|---|---|
| | Speed (cm/s) | Pressure (psi) | (Ω/□) |
| Annealed at 165° C. | x | x | 370 ± 130 |
| Rolled at 165° C. | 10 ± 2 | 50 ± 25 | 26 ± 3 |
| Rolled at 165° C. | 1 ± 2 | 50 ± 25 | 35 ± 15 |
| Rolled at 165° C. | 10 ± 2 | 250 ± 50 | 173 ± 83 |
| Rolled at 165° C. | 1 ± 2 | 250 ± 50 | Open circuit |

When silver nanowire meshes on PET were examined, it was found that rapid speeds (10 cm/s) at 50 psi resulted in the lowest measured sheet resistance of 26±3Ω/□ at a temperature of 165° C. Slower speeds of 1 cm/s at 165° C. led to sheet resistances of 35±15 Ω/□, which is within experimental error, but the standard deviation is somewhat greater. Higher pressures produced silver nanowire meshes with substantially higher sheet resistances, including open circuit (non-conductive) films when high pressures (250 psi) and slow speeds are applied at 165° C. SEM imaging provides an explanation for the damaging effects of high pressure. As can be seen in FIGS. 7A and 7B, at 50 psi pressure with speed range between 1 and 10 cm/s produce continuous nanowire arrays that are in continuous contact with the underlying PET substrate. At higher pressures, on the other hand (FIGS. 7C and 7D), the empty impressions or trenches of the same dimensions as the silver nanowires suggest that they have been removed, leaving a discontinuous network of wires through which current cannot flow in an unimpeded fashion. Therefore, the ideal conditions for rolling the nanowire arrays are, within the range of pressures and speeds tested here, lighter pressure and faster rolling. Under these conditions, the pressure is sufficient to press the nanowires onto the PET, but not sufficiently hard to damage the wires themselves.

Adherence of the Nanowire Mesh to the Substrate:

Adherence of the nanowire meshes to the underlying PET was measured in two ways. First, the standard scotch tape test was applied, in which a piece of scotch tape is pressed firmly onto the nanowire mesh on PET by hand, and then peeled off. Table 4 shows that for a sprayed silver nanowire mesh with no rolling or other treatment, the sheet resistance increases from 370±137Ω/□ to open circuit—the nanowires are presumably removed or disrupted to such an extent that the substrate remained an insulator.

TABLE 4

| Substrate | Pre tape (sheet resistance | Post tape (sheet resistance |
|---|---|---|
| treatment | (Ω/□)) | (Ω/□)) |
| As-deposited | 370 ± 137 | Open circuit |
| Rolled | 37 ± 9 | 167 ± 40 |

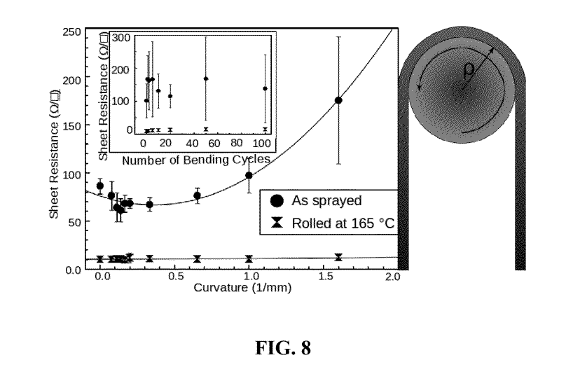

The sample rolled at 165° C., however, shows an increase in sheet resistance from 37±9Ω/□ to 167±40Ω/□. The second test of adherence of the silver nanowires to the PET substrate following rolling was demonstrated through a bending test, in which the flexible substrate was bent around rods of various radii of curvature. FIG. 8 shows that at all the radii of curvature tested (50-0.625 mm), the sheet resistance of the silver nanowire meshes rolled at 165° C. remains constant below 20Ω/□. On the other hand, sprayed silver nanowires that were not rolled had a higher overall sheet resistance, which increased substantially when the radius of curvature dropped below 1.0 mm. Clearly, the silver nanowires adhere strongly to the PET substrate after rolling at this temperature, whereas the as-sprayed films are damaged, possibly due to delamination. Even after 100 bending cycles (FIG. 8, inset), the silver nanowire meshes rolled at 165° C. maintained their low sheet resistance.

Transparent and Translucent Electrodes:

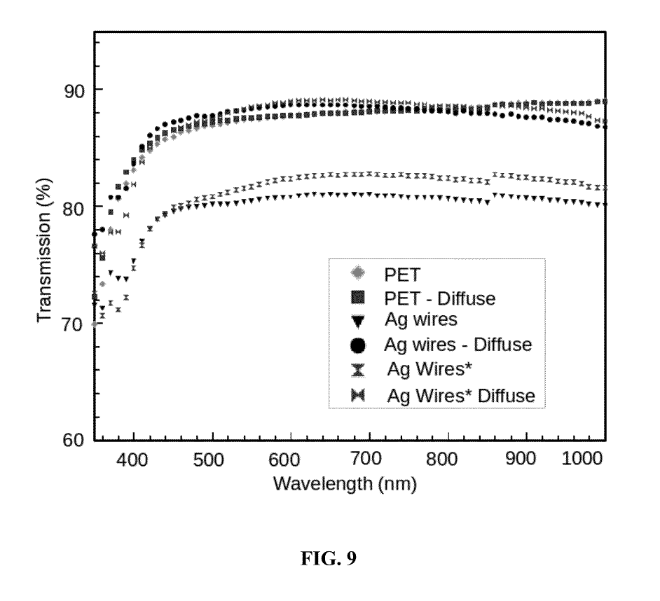

For applications as a transparent or translucent electrode in OPV and OLED devices, conductivity measurements must be supplemented by optical transmissivity studies. Normal and diffuse transmission measurements can provide important information regarding the utility of these nanowire mesh electrodes in architectures that have the requirement of handling light. As can be seen in FIG. 9, the direct and diffuse transmission through the PET substrates (♦ and ▪ respectively) is almost identical, and ranges from 80% to 87% when weighted equally over the wavelengths of 350 nm to 1200 nm. In the case of the silver nanowires meshes, these samples had measured sheet resistances of 185±96Ω/□ and 13±2Ω/□ for the as-sprayed and rolled (at 165° C.) samples, respectively. For both sets of nanowire electrodes (both as-sprayed and rolled), the diffuse transmission is almost identical to the parent PET substrate, and the direct transmission about 7% lower. The figures of merit for the rolled silver nanowire electrodes samples are 122 and 201 for normal and diffuse transmission, respectively, calculated using the following equation that compares the ratio of electrical conductivity to optical conductivity where 188.5Ω is half the impedance of free space, Rₛ is the sheet resistance, and T is the transmission:

$$FOM = \frac{188.5 Ω}{{R}_{s} ( {T}^{1 / 2} - 1 )}$$

A figure-of-merit applicable to industry standards is 220 (De & Coleman, 2010). However, it depends on the application—in OPV devices a higher diffuse transmission means a longer optical path length. For displays the haze might blur the image. But the nanometer size dimension is already substantially less than the eye can resolve for pixels. DOI: 10.1007/s12274-013-0323-9 (Preston, et al., 2013), example of a niche application, DOI: 10.1038/NPHOTON.2012.282 (Ellmer, 2012).

OPV Cells:

In order to demonstrate the applicability of these rolled nanowire mesh electrodes in organic electrodes, a small series of OPV cells were produced based upon the following architecture: PET/Ag nanowires/PEDOT:PSS/P3HT:PC₆₁BM/LiF/Al (Table 5).

TABLE 5

| | | Negative | Short circuit | Open circuit | Fill | | Series | Shunt | |
|---|---|---|---|---|---|---|---|---|---|
| | | bias applied | current | voltage | factor | Efficiency | resistance | resistance | |
| Entry | Electrode | beforehand | (Jsc, mA/cm²) | (Voc, V) | (FF) | (PCE, %) | (Ω-cm²) | (kΩ-cm²) | Yield |
| 1 | ITO | No | 8.7 ± 0.6 | 0.57 ± 0.01 | 0.59 ± 0.03 | 2.9 ± 0.3 | 6.7 ± 0.9 | 1.0 ± 0.5 | 100.00% |
| 2 | Ag mesh, | No | 0 | 0 | 0 | 0 | 2.8 ± 1.1 | 0.003 ± 0.001 | 0.00% |
| | not rolled | | | | | | | | |
| 3 | Ag mesh, | No | 8.0 ± 0.6 | 0.57 ± 0.01 | 0.56 ± 0.02 | 2.5 ± 0.3 | 7.1 ± 1.0 | 1.1 ± 0.6 | 70.00% |
| | rolled | | | | | | | | |
| 4 | Ag mesh, | Yes | 7.1 ± 0.7 | 0.57 ± 0.01 | 0.57 ± 0.01 | 2.3 ± 0.2 | 8.0 ± 0.9 | 1.0 ± 0.6 | 80.00% |
| | not rolled | | | | | | | | |
| 5 | Ag mesh, | Yes | 7.9 ± 0.7 | 0.56 ± 0.01 | 0.57 ± 0.2 | 2.5 ± 0.3 | 7.2 ± 0.8 | 1.2 ± 0.7 | 100.00% |
| | rolled | | | | | | | | |

As can be seen, entry 1, the ITO standard cell, demonstrated a power conversion efficiency (PCE) of 2.9±0.3% and a short circuit current (J_{sc}) of 8.7±0.6 mA/cm². The as-sprayed silver nanowire mesh electrodes (no rolling treatment) on PET did not function (entry 2), and had a PCE of 0% initially. Entry 3, the rolled silver nanowire mesh electrode demonstrated a PCE of 2.5±0.3% and a J_{sc} of 8.0±0.6 mA/cm². The comparison ‘standard’ cell, based upon ITO, entry 1, had a superior PCE due to a higher J_{sc} than the OPV devices that used a nanowire-based transparent electrode. For shorted devices (PCE=0%), when a potential is applied in the negative direction across the samples for a short period of time, performance can often improve. Details are provided in Example 1. As can be seen for the unrolled silver nanowire mesh electrodes, entry 2, these devices initially demonstrated a PCE of 0%, but application of the reverse bias treatment resulted in a large increase in device yield, from 0% to 80%, with a PCE of 2.3±0.2% (entry 4). Yield is defined as the percentage of working devices compared to the number of devices made; for example if 10 devices were made and 7 worked, the yield would be 70%. With the same negative bias application, the rolled silver nanowire device yield increased from 80% to 100% (entry 5). Silver nanowire mesh electrodes have been tested within P3HT/PC₆₁BM cell architecture, and results comparable to these results and ITO standard cells have been observed previously (Angmo & Krebs, 2013; Sachse, et al., 2013; Gaynor, et al., 2011; Yu, et al., 2011).

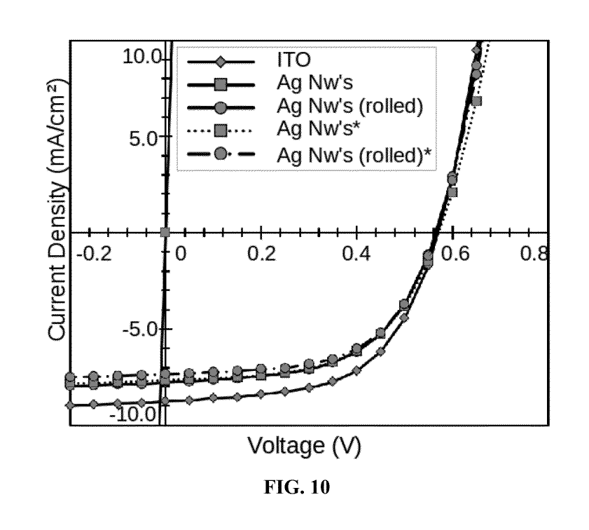

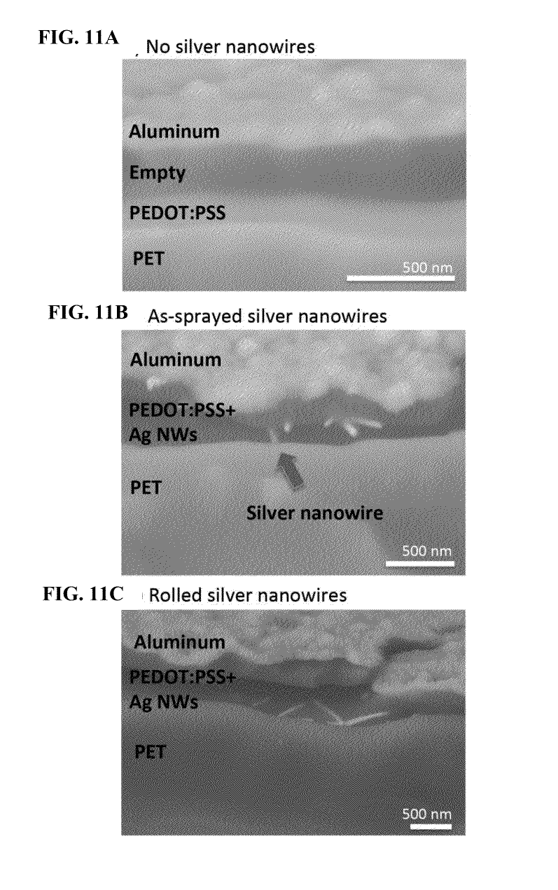

Model OPV devices on PET were prepared, cleaved, and briefly soaked in o-dichlorobenzene, a solvent that is selective for the bulk heterojunction (BHJ), with the goal of partially removing the BHJ to provide an unhindered view of the silver nanowire electrode. The model devices were assembled on PET, and contained the following layers: PET/silver nanowires/PEDOT:PSS/3HT:PC₆₁BM/Al or PEDOT:PSS/P3HT:PC₆₁BM/Al. As can be seen in FIG. 10, the bias, ranging from −1 to −5 V, was applied between the two electrodes on the device. This bias caused a current to flow through the device, in the opposite direction of the device's normal operational mode. With the dimensions of the nanowires being on such a small scale, and the current being forced through the shorting nanowires, the current density through a single nanowire (NW) would be very high. The high current density “melts” or “burns” away any of the nanowire that had caused the devices to short out (see FIGS. 11A-11C). As seen in FIG. 11A, the aluminum top electrode and the layers corresponding to the underlying PEDOT:PSS on the PET substrate are observed; the top Al electrode has not collapsed since there has been only partial removal of the P3HT:PC₆₁BM BHJ. FIG. 11B shows the model cell using an as-sprayed silver nanowire mesh on PET. In places, silver nanowires that are not parallel to the underlying PET substrate can be seen, suggesting the potential for shorting of the device. FIG. 11C reveals the model device using the rolled silver nanowires (at 165° C.), in which the silver nanowire mesh appears topologically flat. Bridging silver nanowires could make contact between the PET and the aluminum top contact in the device, but the flattened mesh would not be expected to bridge the BHJ active layer.

### Example 3

### Reflective Electrode Data

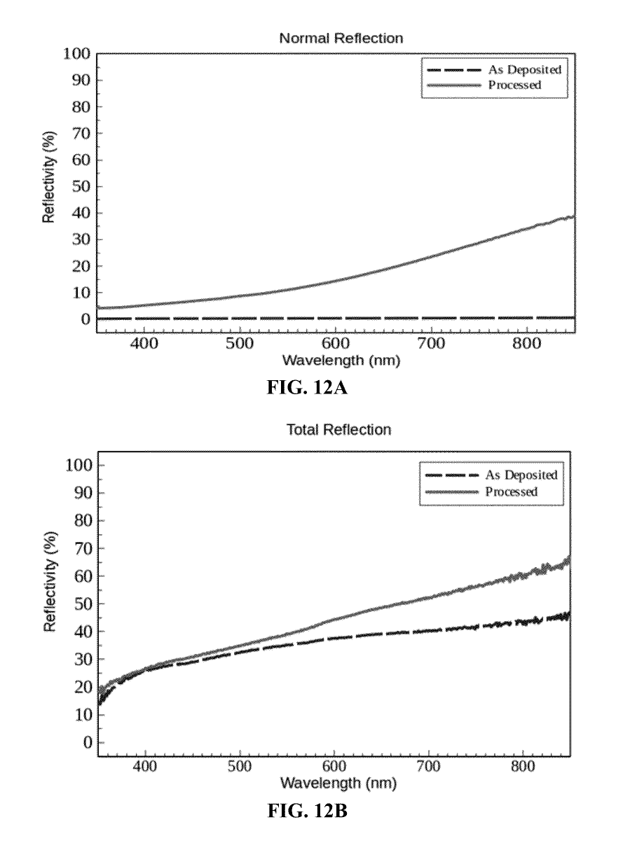

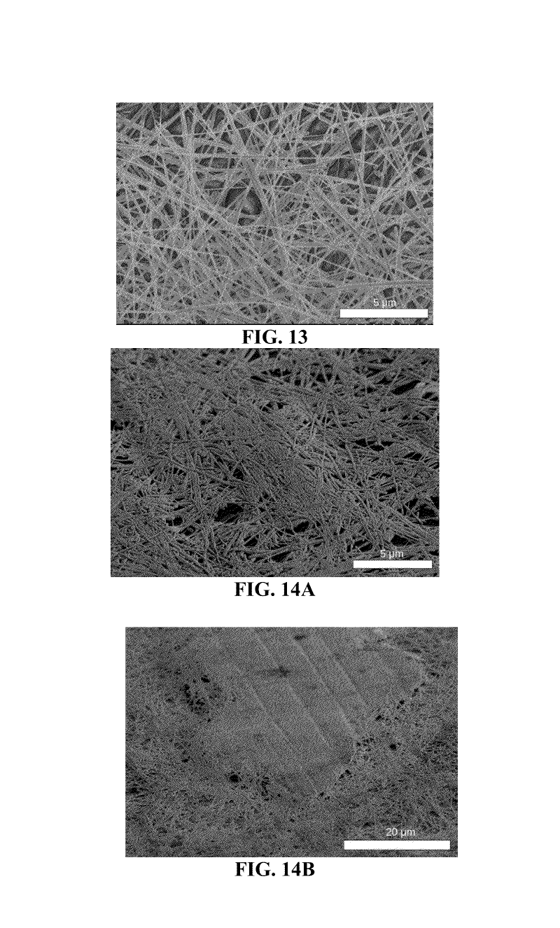

Reflective electrodes using a transparent substrate (PET) were prepared in the same manner discussed above in Example 1 with one difference. Additional nanowires were used to increase the reflectivity of the resulting electrode. FIGS. 12A and 12B provide normal and total reflection data, respectively. The plots in FIGS. 12A and 12B show a comparison between optically thick electrodes that are as deposited, meaning sprayed on the PET and left as is, and processed, meaning sprayed followed by rolling with pressure/heat. The dashed line represents the as-deposited sample while the solid is the processed sample. There is an increase in both the normal reflection and total reflection. Normal reflection refers to specular reflection where in incident angle is equal to the output angle. In this case the angle of incidence was small (˜8°) which can be approximated to normal. The total reflection was measured using an integrating sphere and compared against certified reference standards. An SEM image of an as-deposited nanowire film (FIG. 13) illustrates that the wires are rough with no noticeable deformation from the round shape they have directly following the heat and pressure step. SEM images of processed nanowire films (FIGS. 14A and 14B) show a decrease in surface roughness and a change in film morphology. It is the flattening of the surface on this scale that leads to an increase in reflection by reducing scattering losses throughout the film.

Table 6 shows the effect of processing an optically thick film on sheet resistance. The initial resistance is 2.2 (Ω/□) and drops to 0.48 (Ω/□). Both these values are suitable for electrodes in thin film devices, but the higher reflectivity, the adherence to the underlying substrate, and flatness of the processed samples are where the advantages lie.

TABLE 6

| Sample | Sheet resistance (Ω/□) |
|---|---|
| As deposited | 2.2 ± 0.6 |
| Rolled | 0.48 ± 2 |

### Example 4

### Work function Data

Work Function Modification of the Silver Nanowire Electrodes:

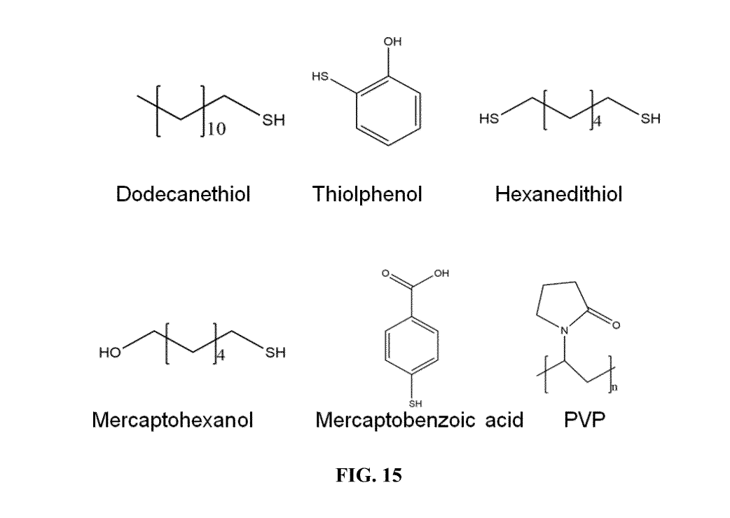

Ligand exchange offers an effective way to modify the properties of the silver nanowires, which is prepared with a layer of the polymer ligand, Polyvinylpyrrolidone (PVP). All previous examples of electrodes were carried out with PVP-coated silver nanowires as they are soluble and stable. To tune the work function, various ligands were used for PVP ligand exchange as given in FIG. 15. The PVP ligand is easy to exchange because of weak binding between the PVP and the silver nanowires surface, they can be easily displaced by α,ω-thiols, resulting in silver-thiol linkages, and the ω group acting as the external terminal group for the silver nanowires. As can be seen in Table 7 below, the work function of spray coated films of as-prepared silver nanowires can be controlled within a range of 4.15 eV (6-mercapto-1-hexanol), to 4.62 eV (4-mercaptobenzoic acid).

TABLE 7

| Ligand | Work Function (eV) |
|---|---|
| PVP | 4.38 |
| Dodecanethiol (DDT) | 4.41 |
| Thiophenol | 4.3 |
| 1,6-hexanedithiol | 4.26 |
| 6-mercapto-1-hexanol | 4.15 |
| 4-mercaptobenzoic acid (MBA) | 4.62 |
| MBA + Peptide Functionalized | 4.20 |
| Nanoparticles (PFN) | |

XPS of Ligand-Exchanged Silver Nanowires.

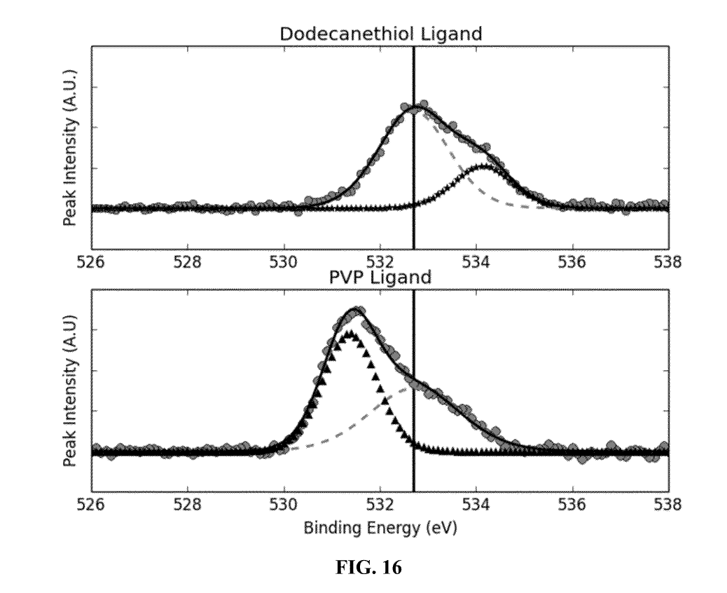

As shown in FIG. 16 the XPS spectrum of the oxygen 1s (O(1s)) peak of silver nanowires, with both the PVP and DDT ligands. Circles represent the raw data.

Top Spectrum (DDT Ligands).

In FIG. 16, the absence of a PVP oxygen peak at 531.4 eV, in the DDT spectrum suggests the ligand exchange went to completion and there was no carbonyl oxygen from the PVP remaining. The sample initially shows two features, with one at 532.7 eV (dashes) and the other at 533.9 eV (crosses). The 533.9 eV feature may be attributed to oxygen in the sulfate form, while the feature at 532.7 eV can be attributed to the oxygen in AgO or Ag₂O.

Bottom Spectrum (PVP Ligands).

The bottom plot is for the Ag NW's coated with PVP. This plot again shows two features, with one at 532.7 eV (dashes) and another at 531.4 eV (triangles). The feature at 531.4 eV corresponds to carbonyl oxygen in PVP, with the feature at 532.7 eV corresponding to AgO, or Ag₂O.

XPS Verification of Ligand Exchange.

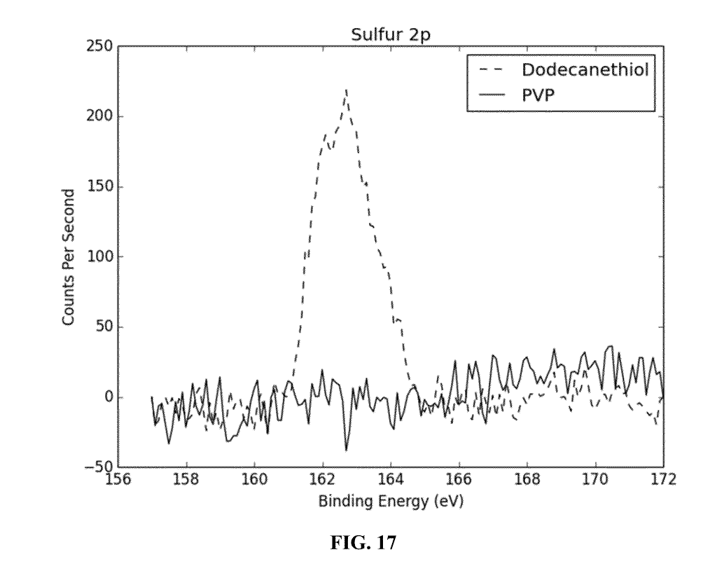

XPS spectra of the sulfur features on nanowires with a PVP ligand, and a dodecanethiol ligand are shown in FIG. 17. This result confirms the presence of the dodecanethiol ligand as sulfur peak recognized in spectrum.

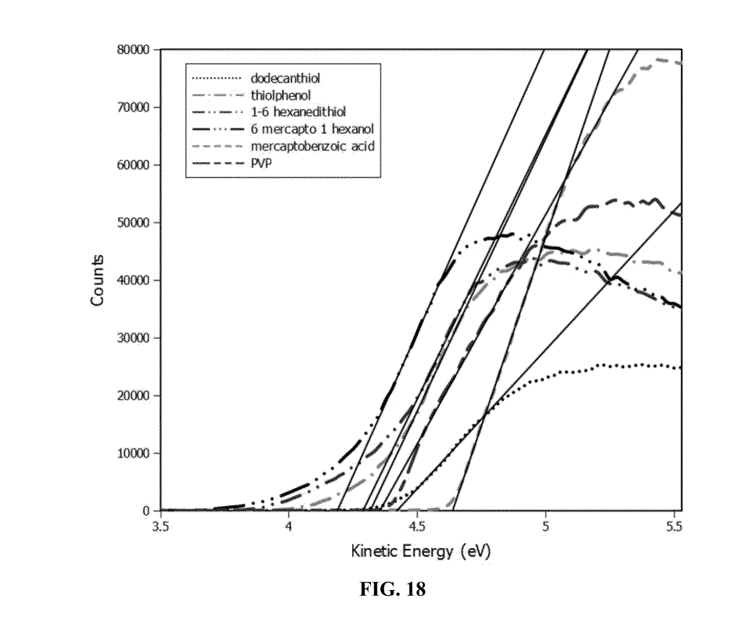

UPS (ultraviolet photoelectron spectroscopy) of silver nanowires with different ligands functionalization is provided in FIG. 18. These data were used to determine the work function. As shown in Table 7 (above), the ligand can clearly alter the work function. The work function is reported as the intercept of the solid black linear regression of the experimental data (patterned lines) with the x-axis. Each of the patterned curves corresponds to a different ligand, while the black lines are the fits to each raw data set.

1. A method for making a transparent, opaque, or reflective electrode, the method comprising:
(a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate;
(b) applying heat to either the first surface or the second surface of the substrate, or both, with at least a first heating source or with at least a first and second heating source such that the micro- or nanostructures or the first surface of the substrate are heated to a temperature that is greater than the glass transition temperature or the Vicat softening temperature of the substrate and less than the melting point of the substrate;
(c) applying a sufficient amount of pressure to either the first surface or the second surface of the substrate, or both, with at least a first pressure source or with a first and second pressure source such that the first surface of the substrate and the micro- or nanostructures are pressed together so as to form a conductive layer that is attached to the first surface of the substrate; and
(d) removing the first pressure source or the first and second pressure sources to obtain an electrode,
wherein the sheet resistance of the electrode in step (d) is less than the sheet resistance of the substrate/micro- or nanostructure combination in step (a), and
wherein the transparency, opacity, or reflectivity of the electrode is dependent on the amount of micro- or nanostructures deposited on the first surface of the substrate in step (a).

2. The method of claim 1, wherein a transparent electrode is obtained having a total transmittance of incident light of at least 50, 60, 70, 80, or 90%, a specular transmission of greater than 50%, and a diffuse transmission of greater than 65%.

3. The method of claim 1, wherein a reflective electrode is obtained having a specular reflection of greater than 10% and a diffuse reflection of greater than 50%.

4. The method of claim 1, wherein an opaque electrode is obtained.

5. The method of claim 1, wherein the substrate is a transparent.

6. The method of claim 5, wherein the transparent substrate is a flexible or elastomeric polymeric substrate.

7. The method of claim 6, wherein the flexible or elastomeric polymeric substrate is a polyethylene terephthalate (PET), a polycarbonate (PC) family of polymers, polybutylene terephthalate (PBT), Poly(1,4-cyclohexylidene cyclohexane-1,4-dicarboxylate) (PCCD), Glycol modified polycyclohexyl terephthalate (PCTG), Poly(phenylene oxide) (PPO), Polypropylene (PP), Polyethylene (PE), Polyvinyl chloride (PVC), Polystyrene (PS), polymethamethyl acrylate (PMMA), Polyethyleneimine (PEI) and its derivatives, Thermoplastic elastomer (TPE), Terephthalic acid (TPA) elastomers, poly(cyclohexanedimethylene terephthalate) (PCT), Polyethylene naphthalate (PEN), Polyamide (PA), Polystyrene sulfonate (PSS), or Polyether ether ketone (PEEK) or combinations or blends thereof.

8. The method of claim 7, wherein the substrate is PET.

9. The method of claim 1, wherein heating step (b) and pressure step (c) are performed simultaneously or substantially simultaneously or wherein the heating step (b) is performed before pressure step (c).

10. The method of claim 9, wherein the first surface of the substrate in step (b) is heated with a heating source and pressure is applied in step (c) to the second surface of the substrate with a pressure source.

11. A method for making a conductive material comprising a substrate and a conductive layer that is attached to said substrate, the method comprising:
(a) providing a substrate comprising a first surface and an opposite second surface, wherein micro- or nanostructures are disposed on at least a portion of the first surface, and wherein the first surface is not pre-conditioned to increase attachment between the micro- or nanostructures and the substrate;
(b) applying heat to either the first surface or the second surface of the substrate, or both, with at least a first heating source or with at least a first and second heating source such that the micro- or nanostructures or the first surface of the substrate are heated to a temperature that is greater than the glass transition temperature or the Vicat softening temperature of the substrate and less than the melting point of the substrate;
(c) applying a sufficient amount of pressure to either the first surface or the second surface of the substrate, or both, with at least a first pressure source or with a first and second pressure source such that the first surface of the substrate and the micro- or nanostructures are pressed together so as to form a conductive layer that is attached to the first surface of the substrate; and
(d) removing the first pressure source or the first and second pressure sources to obtain the conductive material,
wherein the sheet resistance of the conductive material in step (d) is less than the sheet resistance of the substrate/micro- or nanostructure combination in step (a).

12. The method of claim 11, wherein the substrate or the micro- or nanostructures in step (b) are heated to a temperature within at least 80% of the Vicat softening point of the substrate.

13. The method of claim 11, wherein heating step (b) and pressure step (c) are performed simultaneously or substantially simultaneously or wherein the heating step (b) is performed before pressure step (c).

14. The method of claim 13, wherein the first surface of the substrate in step (b) is heated with a heating source and pressure is applied in step (c) to the second surface of the substrate with a pressure source.

15. The method of claim 11, wherein the conductive layer is attached to the substrate such that it retains its conductivity after being subjected to a scotch tape test or a bending test.

16. The method of claim 11, wherein the micro- or nanostructures are disposed directly onto the surface of the substrate in step (a) via solution based processing.

17. The method of claim 16, wherein the solution based processing comprises spray coating, ultra sonic spray coating, roll-to-roll coating, ink jet printing, screen printing, drop casting, spin coating, dip coating, Mayer rod coating, gravure coating, slot die coating, or doctor blade coating.

18. The method of claim 11, wherein the micro- or nanostructures are coated with an organic ligand comprising a thiol, a phosphorus, an amine or a combination of thereof.

19. The method of claim 18, wherein the work function of the conductive material is tuned to a targeted work function by the ligand.

20. The method of claim 19, wherein the conductive material has a work function of up to 8 eV, preferably from 2 to 8 eV, or more preferably from 3 to 6 eV.

21. The method of claim 20, wherein the ligand is polyvinylpyrrolidone (PVP), dodecanethiol (DDT), thiophenol, 1,6-hexanedithiol, 6-mercapto-1-hexanol, or 4-mercaptobenzoic acid (MBA), or a combination thereof.

22-62. (canceled)
